(19) United States
(12) Patent Application Publication
(10) Pub. No.: US 2017/0118880 A1
(43) Pub. Date: Apr. 27, 2017

(54) SUPPLEMENTAL LIGHTING FOR READING INFORMATION ON CIRCUIT BOARDS FOR USE WITH A BOND HEAD ASSEMBLY SYSTEM

(71) Applicant: Duetto Integrated Systems, Inc., Islandia,, NY (US)

(72) Inventors: ANTHONY FARACI, Commack, NY (US); Gary N. SORTINO, Baldwin, NY (US)

(73) Assignee: Duetto Integrated Systems, Inc., Islandia, NY (US)

(21) Appl. No.: 15/390,049

(22) Filed: Dec. 23, 2016

Related U.S. Application Data
(63) Continuation-in-part of application No. 12/377,268, filed on Mar. 24, 2010, now abandoned.
Application No. 12/377,268 is a continuation-in-part of application No. 14/825,462, filed on Aug. 13, 2015.

(51) Int. Cl. H05K 13/08; H05K 13/00

(52) U.S. Cl. CPC H05K 13/08; H05K 13/0015

(57) ABSTRACT

Disclosed is an integrated bonding station for bonding laminate elements in a selected stack orientation, at least one of the laminate elements including a barcode on a surface thereof, the integrated boding station including a barcode reader assembly may include: a barcode reader; a direct lighting assembly being configured to direct light onto a surface of the at least one laminate element; a low angle lighting assembly being configured to direct light near the surface; and a back lighting assembly being configured to direct light onto an opposing side of the surface. Each of the direct lighting assembly, low angle lighting assembly, and back lighting assembly may be configured to provide light of a selected wavelength and of a selected intensity.

### CROSS REFERENCE TO RELATED APPLICATIONS

This application claims priority from co-pending U.S. pat. app. Ser. No. 12/377,268 filed Mar. 24, 2010 and U.S. pat. app. Ser. No. 14/825,462 filed Aug. 13, 2015, the entire contents of both of which are hereby incorporated by reference.

### FIGURE SELECTED FOR PUBLICATION

FIG. 30

### BACKGROUND OF THE INVENTION

Field of the Invention

The present invention generally relates to a bonding station assembly, and more particularly, to a lighting assembly for use with the bonding station assembly to facilitate reading of barcode information on a surface of one or more laminate elements to be bonded.

Description of the Related Art

The related art involves the use of different types of alignment systems each offering advantages and disadvantages. Presently these differing types include “pin-based” and “riveted-type” registration systems in laminated structure manufacturing. While each system succeeds in fixing multiple laminated structures relative to each other, each system also provides an unacceptable alignment tolerance level addressed by the present invention.

There are many tolerances associated with the production of a circuit board. Unfortunately, these combined errors or “tolerance errors” build up throughout the course of lamination imaging and lamination tooling and ultimately have an exponential impact on alignment accuracy. With the increasing reduction in dimensional circuit design these tolerance errors are unacceptable. We will examine the punched or drilled hole tolerances below, at different stages of the manufacturing process.

The tolerance or alignment errors resulting from conventional alignment systems are also revealed through the process of imaging inner layers of an assembled block of laminated members. Imaging inner layers reveals internal alignment errors.

When imaging inner layers, imaging for front-to-back is typically performed using two methods, (i) pinning the artwork to holes on the inner layer or (ii) roughly imaging the circuit pattern to the edges of the inner layer (so called edge-imaging).

In the first method, the conventional tooling holes that were used to image the circuit pattern on the inner layer are also used to align the layers to each other in lamination. The downside to this method is that typically the same holes are used; and consequently, any distortion relative to these holes will have a negative affect as the inner layer is processed throughout the remainder of the lamination process. This problem is greatly affected during lay-up and as the layer thickness is reduced.

In the second method (edge imaging), the hole tolerance for imaging has been eliminated, and this is much more accurate as camera assisted imaging is now possible. The newer exposure machines can now align the front and back artwork via a CCD camera positioning system, by doing so they minimize the tolerances of the punches holes in the artwork as well as in the innerlayers. Unfortunately, this edge imaging method still requires the use of holes for ultimate alignment of a completed lamination and hence still incurs alignment error.

A conventional manufacturing step involves attempting to align the layers prior to lamination. This step in the manufacturing process is conventionally accomplished by many different methods; the most common methods in use today are pin lamination, riveting, and pin bonding.

In “pin Lamination,” systems the most common tooling pattern is the 4-slot centerline tooling. The main advantage of this tooling scheme is that it allows for easier lay-up than lay-up on four round holes. The slots compensate any material movement in the etching process (allowing and encouraging X-Y shifting), whereas the use of simply four round holes would cause distortion on the inner layer when pinned to four-fixed pin in a lamination plate (four round hoes prevents shifting between layers causing gapping, and ultimately layer shifting. So if the slots are used it is conventionally easier to lay-up and buckling is similarly minimized, but there are many tolerances error associated with this process. Unfortunately, these tolerances exist regardless of the numbers of cameras used on a post-etch punch process.

Referring now to FIG. 1, in reviewing the impact of punch and slot alignment systems, the multiple error-sources are noted on Table 1 (FIG. 1) along with the associated error ranges. In reviewing FIG. 1 (Table 1), it should be noted that even under the best conditions, layer-to-layer registration capability with pin lamination is at best approximately 50-75 microns (um).

Finally, as a further disadvantage in the conventional alignment arts, pin lamination is not flexible when changing panel sizes, shifting between panel sizes for custom lamination sets, etc. When changing panel sizes, a customer needs to purchase different lamination and separator plates for each panel size to be processed, and this is extremely expensive.

Referring now to FIG. 2 (Table 2), in conventional “riveting systems,” the main advantage of this tooling scheme is that it allows for more flexibility in selection of panel sizes than pin lamination (because rivet holes may be positioned as needed). Unfortunately, this process also has many of the same detrimental tolerance issues.

These detrimental tolerance issues include the need to line-up holes target locations prior to riveting, the need to punch or drill the holes, and ultimately after hole-creation the layers must be placed on pins prior to riveting to maintain alignment during the riveting process. In sum, the conventional riveting system tooling hole tolerances are the same as in pin lamination, but there are also the following tolerances associated with riveting. These tolerances are summarized generally in FIG. 2.

As noted in FIG. 2, the layer shift due to rivet distortion itself is a mechanical error that is very difficult to overcome, thus making the riveting generally a process for low layer count and low-density boards.

Finally, in conventional “pin bonding systems,” much like riveting, the main advantage of this tooling scheme is that it allows for more flexibility in choosing panel sizes than in the above-discussed pin lamination systems. Unfortunately, pin bonding systems also possess some of the same tolerances.

The tolerance issues in pin bonding systems include that the line-up holes prior to bonding must be punched or drilled, and that the layers must be physically or mechanically placed on pins prior to bonding for the alignment. These tooling hole tolerances and the positioning tolerances are the same as in pin lamination.

Ultimately, after conventional alignment systems the bonding process, whether accomplished by hot heads, ultrasonic or inductive is essentially the same. During initial bonding, the so called pre-preg (resin sheets) at certain points, typically at six points on the long edge of the panel, is heated so that the resin forms a bond point between sheets. During this conventional bonding process, the results from pin bonding are usually better than pin lamination; and this is because the lay-up is performed on the same template for a certain panel size. This is because in conventional pin lamination the lay-up is on long pins and on different lamination plates that have different tolerances from pin to pin.

Of the different methods discussed, the pin bonding is the most flexible, this eliminates the costly tooled lamination and separator plates, the copper foil does not need to be punched, and there are no consumables required, such as lamination pins or rivets.

Ultimately, what is not appreciated by the prior art is: (a) the need for a highly accurate and repeatable circuit board laminate registration system that is flexible, particularly one that does not magnify error in a multi-layer set-up, but remains instead within a predictable and calculable tolerance range; (b) the need for a repeatable alignment system and structure that enables induced heating for multi-layer systems; (c) the need for a pre-alignment and imaging station for determining a pre-assembly assignment position; and (d) the need for an in-situ pin-less-alignment system.

Further, identification information is often placed on the printed circuit board. There are several ways that this information is placed on the circuit board. The most common is to etch it onto the surface of the printed circuit board using the same process that is used to create the circuitry. Additionally, there are other processes that can place information onto printed circuit boards such as silk screening, ink jet printing, and laser ablading. Printed circuit boards may be manufactured by directly printing copper and/or other conductive materials onto the printed circuit board substrate which would include the information, which may be of a barcode format that is readable both humans and/or vision systems. Reading information that has been etched, printed, or otherwise placed onto a printed circuit board may be difficult because of the range of conductive material finishes, which are typically a form of oxide, and the range of available substrate (e.g., core or inner layer) materials available for printed circuit boards. Conventionally, lighting may be inadequate to provide an image of sufficient quality to read the bar code.

### ASPECTS AND SUMMARY OF THE INVENTION

The present invention relates to a bonding station for bonding laminate elements in a selected stack orientation. During assembly, it may be desirable to read barcode information printed on surfaces of the laminate elements to be bonded. However, due to variances of the surfaces, colors, etc., reading the barcode information may difficult or hampered by inadequate lighting conditions. To address this issue, as disclosed herein, a bonding station may be provided with a means to supplement lighting to improve image quality of an image of a bar code which may be on the printed circuit board and viewed by an imaging/vision system. In particular, direct lighting from a similar location as the camera of barcode reader may be provided. In addition, low angle lighting from near the surface of the material within the information on it may be provided. Further, backlighting may be provided that may light through the printed circuit board and illuminate the information on the material surface. The intensity and wavelength of the light may be selected based on the material on which the barcode is disposed (e.g., etched or imprinted).

In accordance with the present disclosure, provided herein is a integrated bonding station for bonding laminate elements in a selected stack orientation, at least one of the laminate elements (which may be or include metallic material or surfaces) including a barcode on a surface thereof, the integrated boding station including a barcode reader assembly may include: a barcode reader; a direct lighting assembly being configured to direct light onto a surface of the at least one laminate element; a low angle lighting assembly being configured to direct light near the surface; and a back lighting assembly being configured to direct light onto an opposing side of the surface. Each of the direct lighting assembly, low angle lighting assembly, and back lighting assembly may be configured to provide light of a selected wavelength and of a selected intensity. Each of the direct lighting assembly, low angle lighting assembly, and back lighting assembly are configured to provide light of a selected wavelength and of a selected intensity. A diffuser may be configured to be placed between at least one of the lighting assemblies and the barcode to be read. The light provided may have an intensity, pulse, and/or pulse width that are controlled and/or modulated.

The above and other aspects, features and advantages of the present invention will become apparent from the following description read in conjunction with the accompanying drawings, in which like reference numerals designate the same elements.

### BRIEF DESCRIPTION OF THE DRAWINGS

A further understanding of the present invention can be obtained by reference to a preferred embodiment set forth in the illustrations of the accompanying drawings. Although the illustrated preferred embodiment is merely exemplary of methods, structures and compositions for carrying out the present invention, both the organization and method of the invention, in general, together with further objectives and advantages thereof, may be more easily understood by reference to the drawings and the following description. The drawings are not intended to limit the scope of this invention, which is set forth with particularity in the claims as appended or as subsequently amended, but merely to clarify and exemplify the invention.

For a more complete ‘understanding of the present invention, reference is now made to the following drawings in which:

FIG. 1 is a table (Table 1) of conventional alignment errors for punched hole and slot type systems.

FIG. 2 is a table (Table 2) of conventional riveting alignment errors in a riveting type alignment system.

FIGS. 3A and 3B represent a cross-sectional view of the proposed pin-less registration system following lamination and post-bonding with FIG. 3A including non-uniform layers and FIG. 3B including uniform layers.

FIG. 4 is a graphic comparison between traditional registration and the proposed pin-less registration.

FIG. 5 is an exemplary image of a lay-up book without holding pins enabled by one aspect of the proposed invention.

FIG. 6 is an exemplary image of a lay-up book using external holding pins enabled by an aspect of the proposed invention.

FIG. 7 is a perspective view of a multi-camera measurement station according to one aspect of the present invention.

FIG. 8 is a perspective view of a pin-less registration system (PRS) device according to one embodiment of the present invention.

FIG. 9 is a close-up view of an operator loading station as shown in FIG. 8.

FIG. 10 is a perspective view of an internal alignment table assembly within the PRS system.

FIG. 11 is a side view of an alignment table assembly in FIG. 10.

FIG. 12 is a top view of an alignment table assembly as in FIG. 10

FIG. 13 is a left-side end view of an alignment table assembly as in FIG. 10.

FIG. 14A is a side view of an alignment assembly as in FIG. 13 noting close up detail A.

FIG. 14B is a close up view of detail A in FIG. 14A.

FIG. 15 is a partial exploded view of a cam positioning assembly in the alignment table assembly in FIG. 10.

FIG. 16A is a side view of an alignment assembly as in FIG. 11 noting close up detail B.

FIG. 16B is a cut-away side view of a slide bearing assembly from detail B in FIG. 16A.

FIG. 17 is an exploded perspective view of a bearing assembly.

FIG. 17A is a side assembled view of the bearing in FIG. 17.

FIG. 18A is a top view of the alignment table assembly as in FIG. 12 noting section cut detail I-I of a bearing assembly.

FIG. 18B is a cross-sectional view along section I-I in FIG. 18A.

FIG. 19A is a side view of a bearing assembly.

FIG. 19B is a cross-sectional view along section II-II in FIG. 19A.

FIG. 20 is a perspective view of an adjustable view of an adjustable bond head assembly and system employing separable bonding head members.

FIG. 21 is a side perspective view of an adjustable bond head assembly arranged with a layered stack during an assembly step.

FIGS. 21A through 21D are planar elevational views of alternative bonding pad configurations.

FIG. 22 is a perspective exploded view of an individual bond head assembly.

FIG. 23 is a partially cut-away top view of an assembled bond head assembly.

FIG. 24 is a sectional view along line 5-5 in FIG. 4 depicting assembled bond head construction.

FIG. 25 is a side elevational view of mobile top and bottom bond head assemblies positioned relative to a support plate and a sheet or stack of sheets prior to a bonding step.

FIG. 26 is a side elevational view of mobile top and bottom bond head assemblies positioned close to a just-bonded stack of sheets noting the direction of sheet and bond head cooling offered by the presently proposed cooling systems.

FIG. 27 is a perspective pictorial view of a unified bonding system containing a loading station, an alignment station; and multiple bonding stations for enhanced efficiency.

FIG. 28 is a graph depicting the coil turns to heat rate effect over time for differing coil turn numbers between top and bottom bond head assemblies.

FIG. 29A is a perspective view of a stack of printed circuit boards.

FIG. 29B is a perspective view of indicated area A of FIG. 29A.

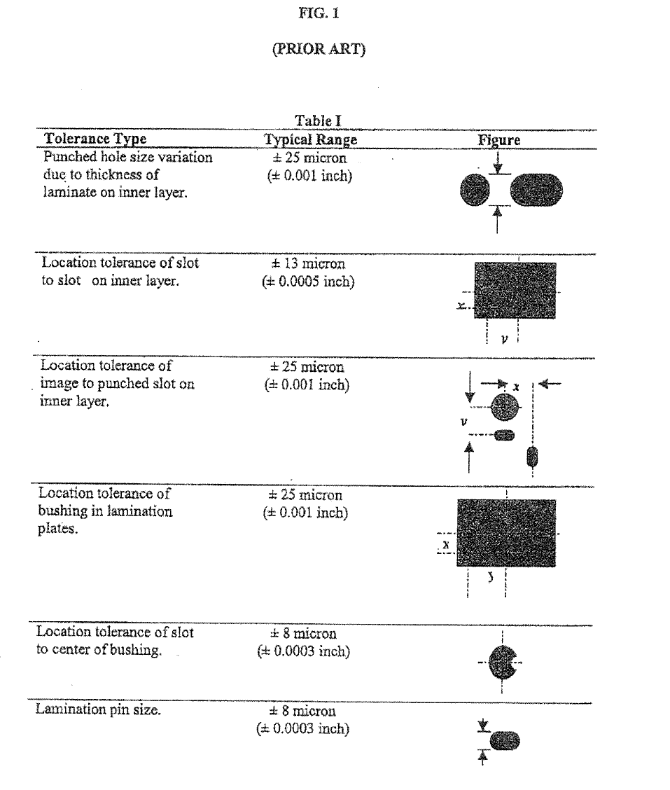

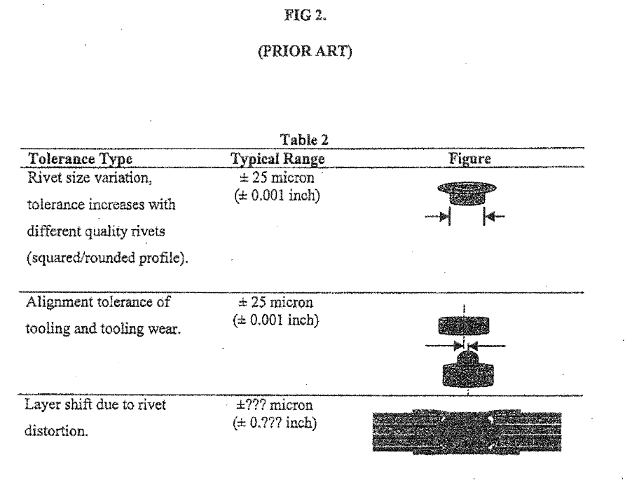

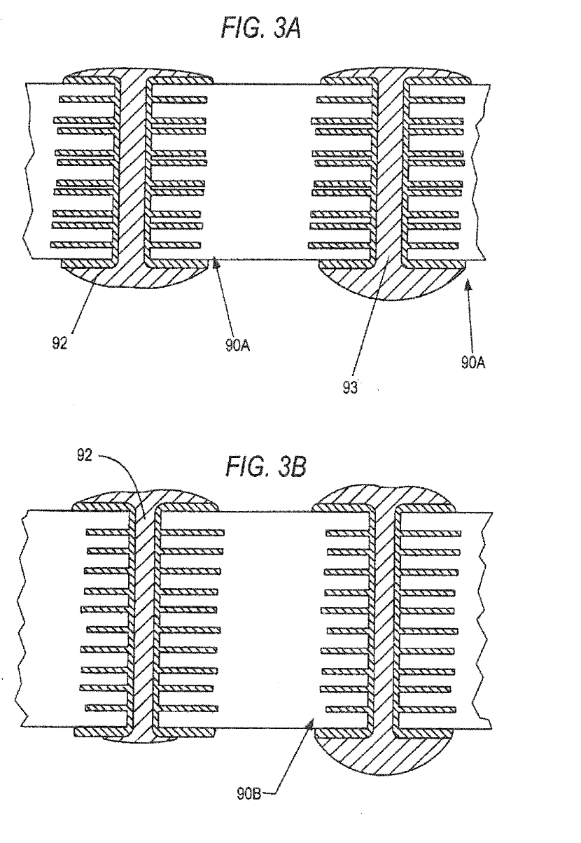

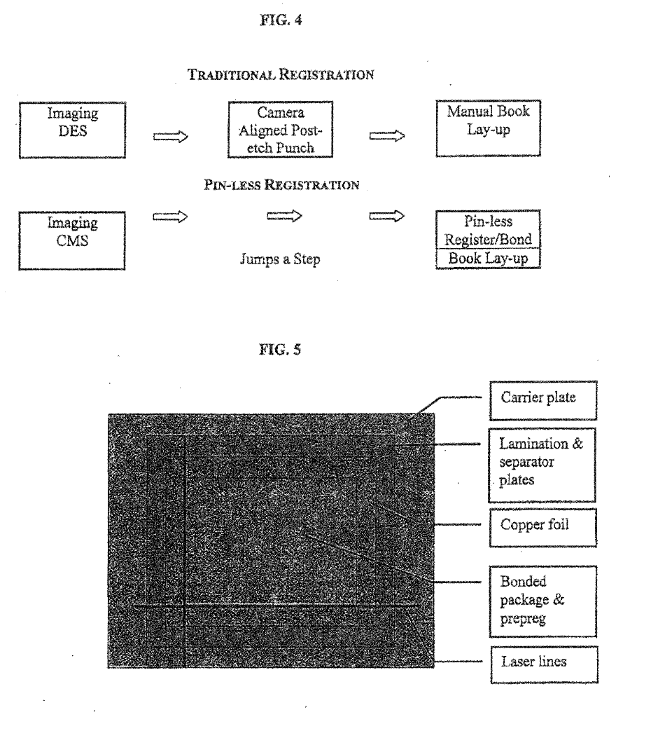

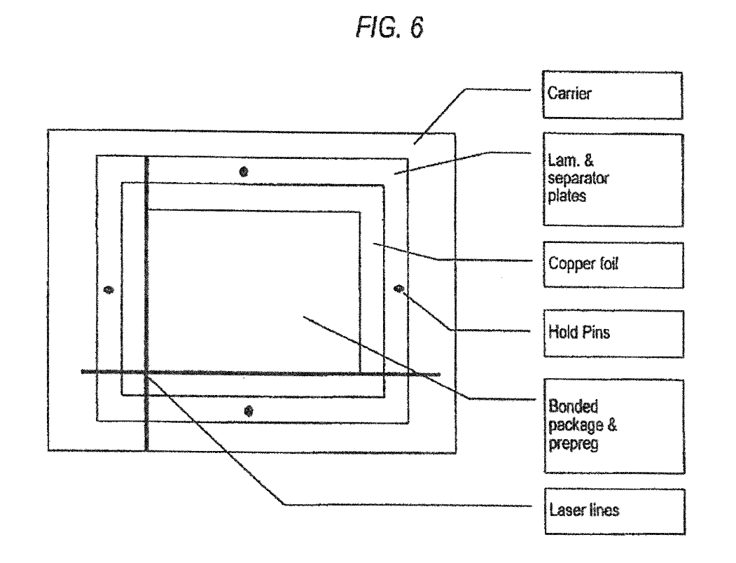

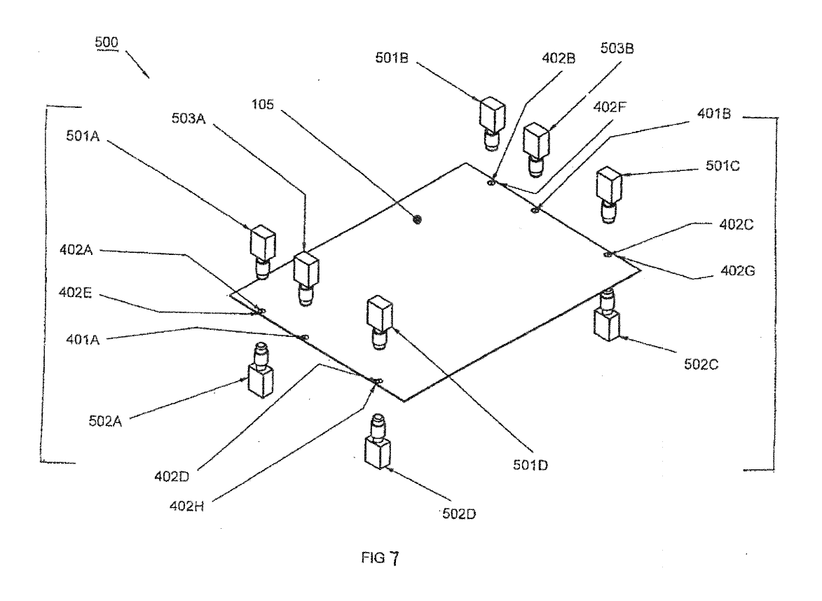

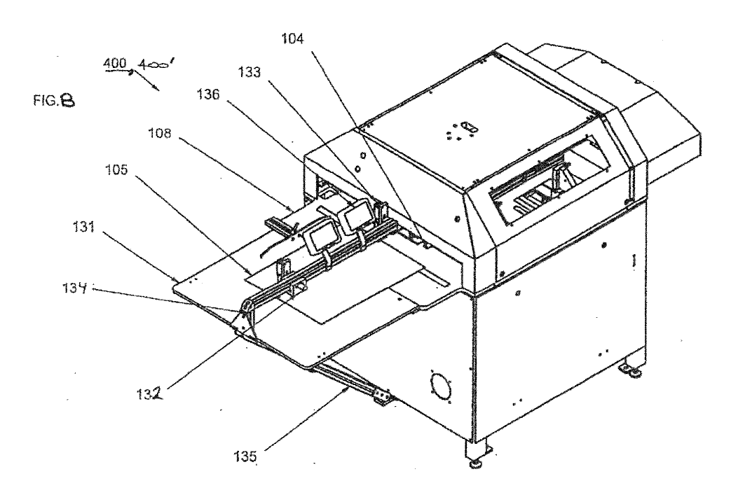

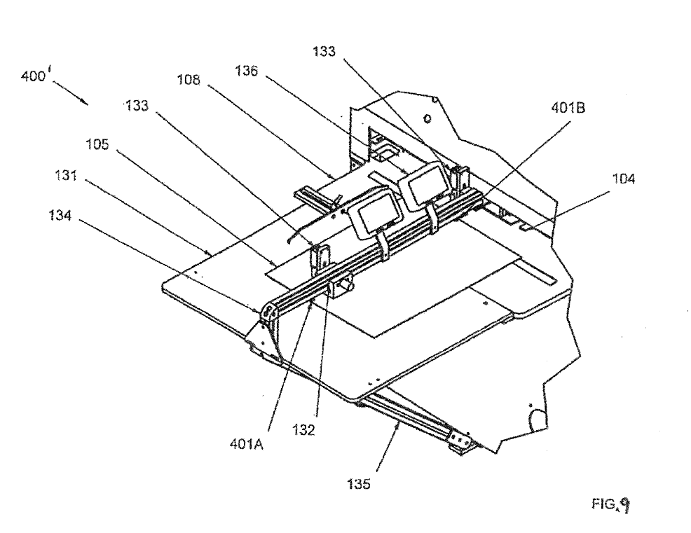

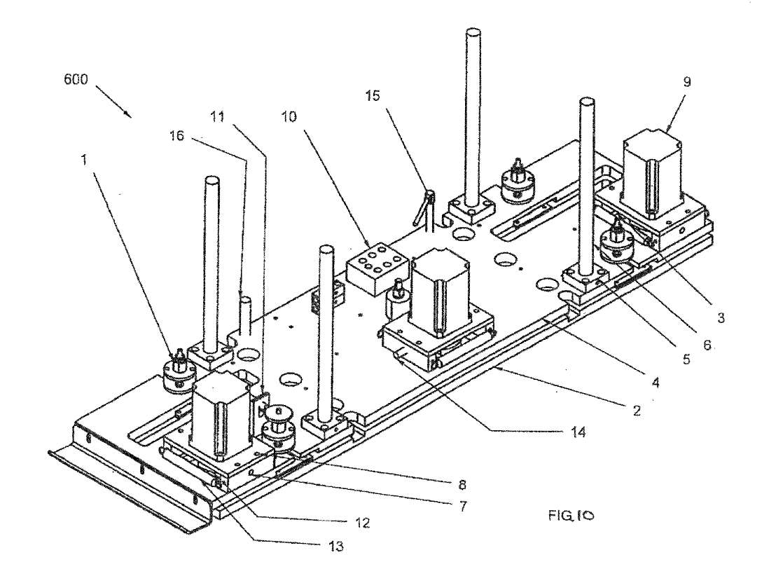

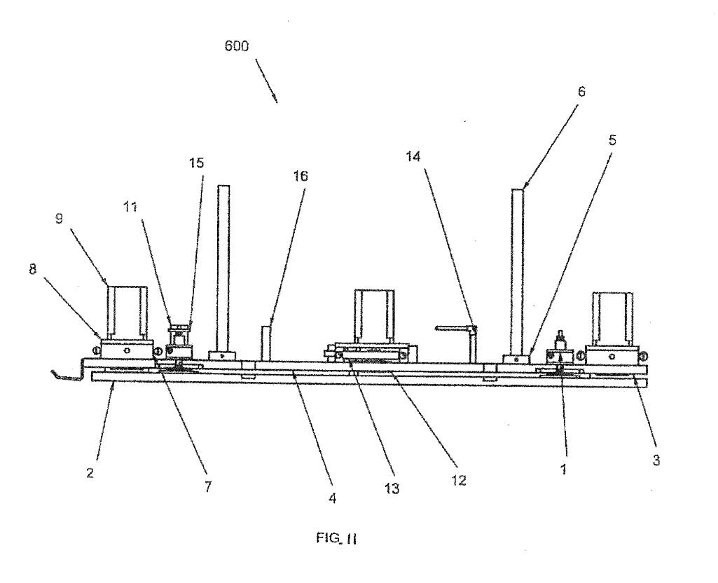

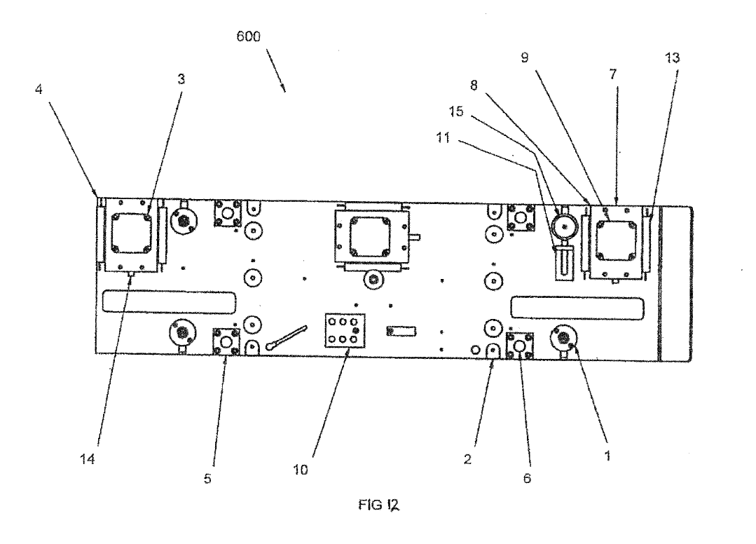

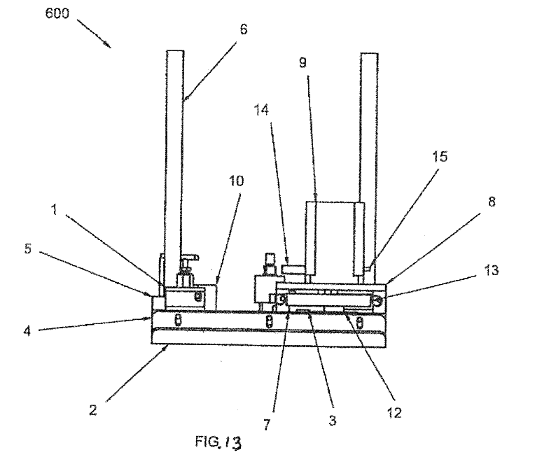

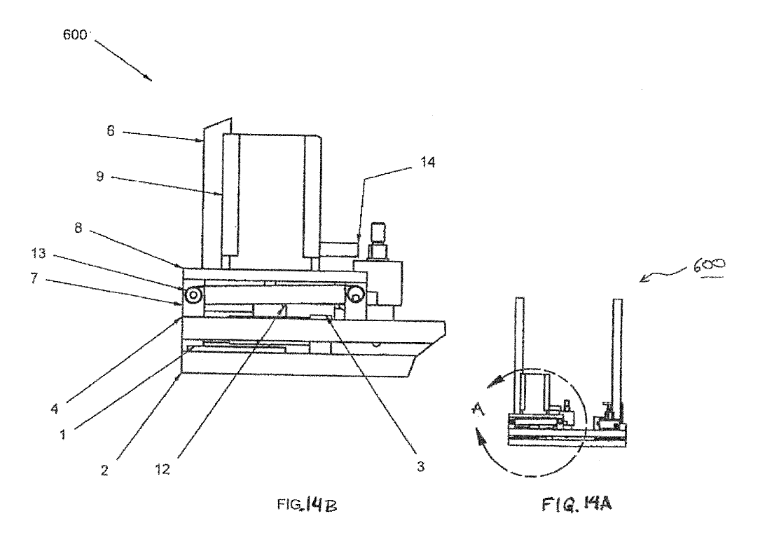

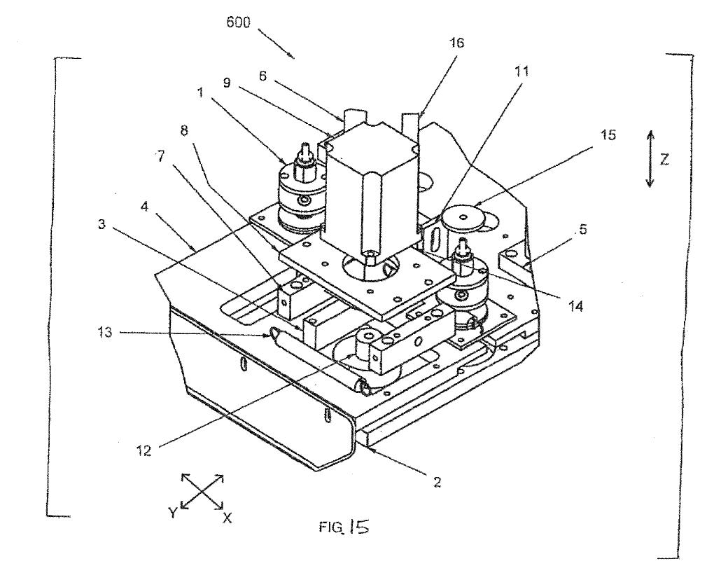

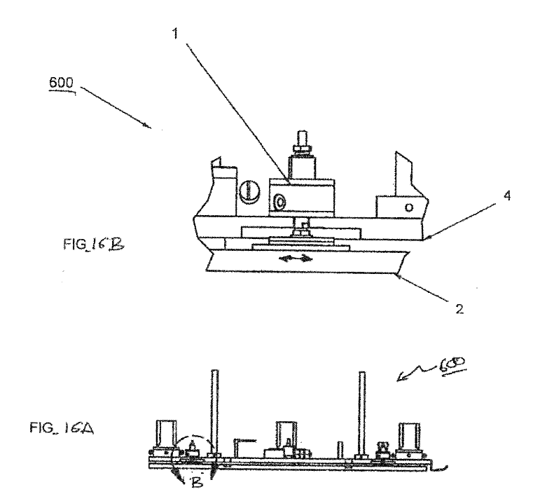

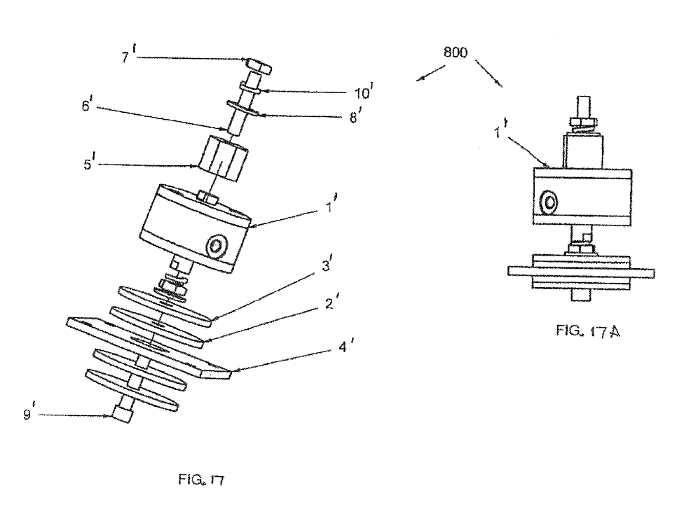

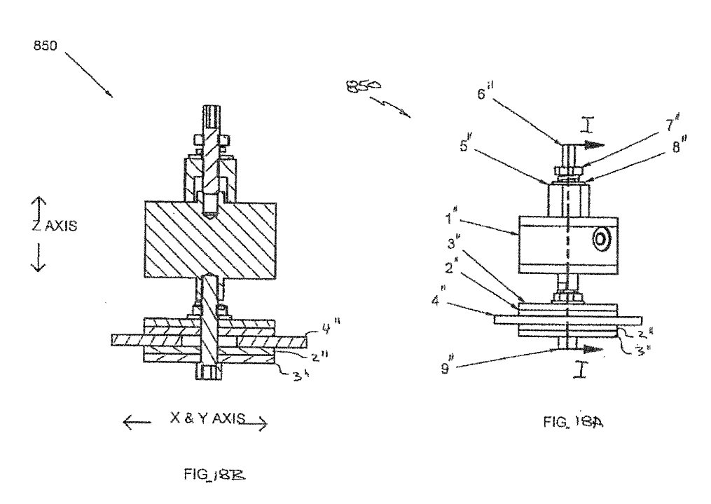

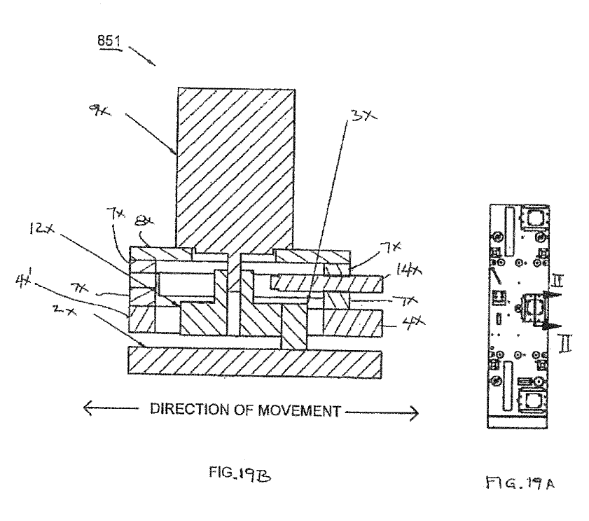

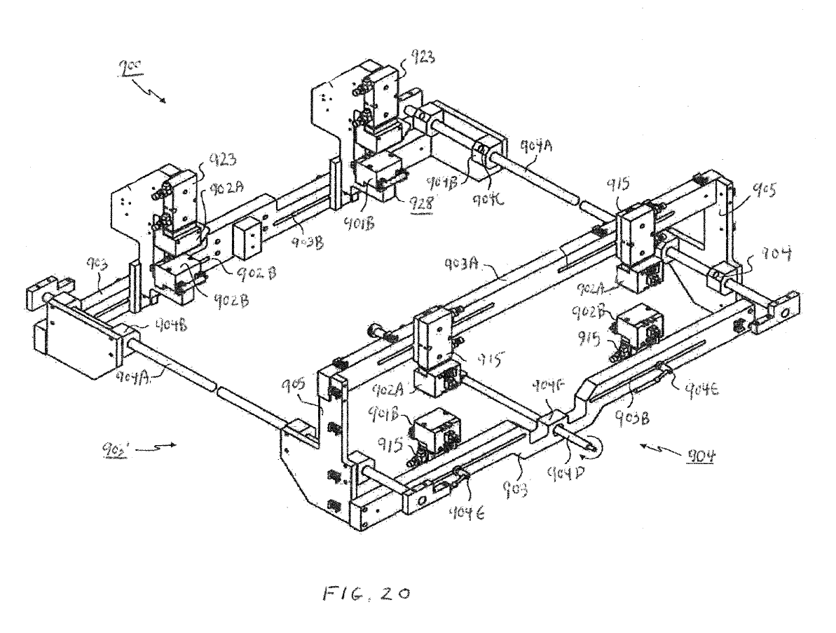

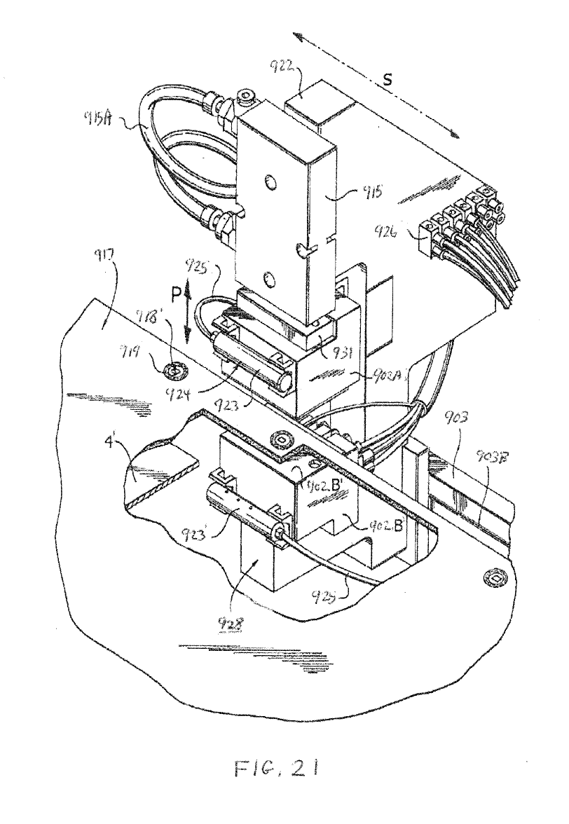

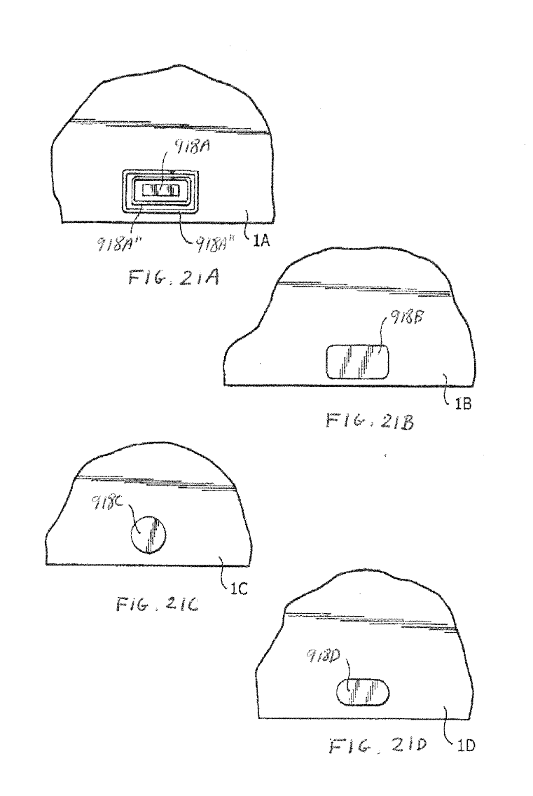

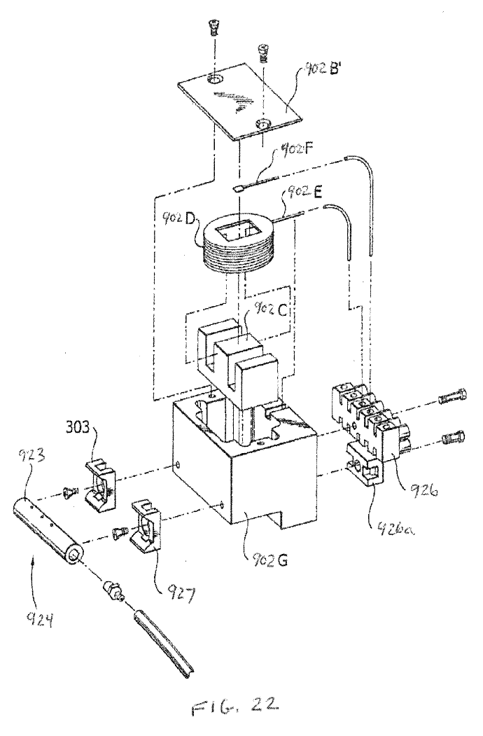

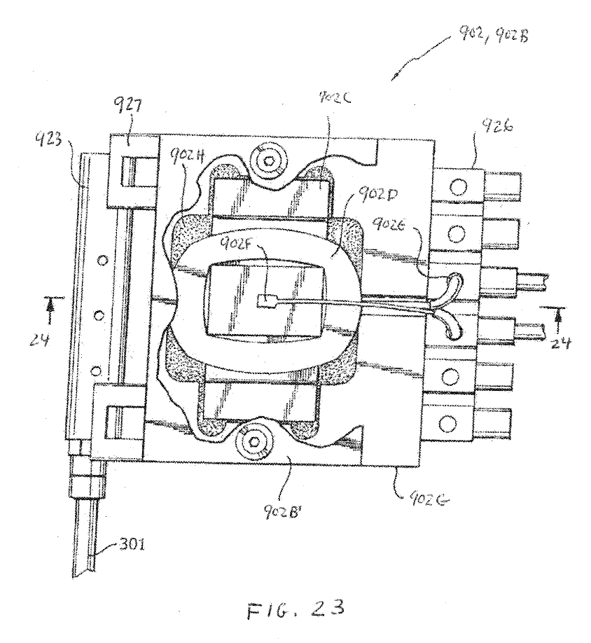

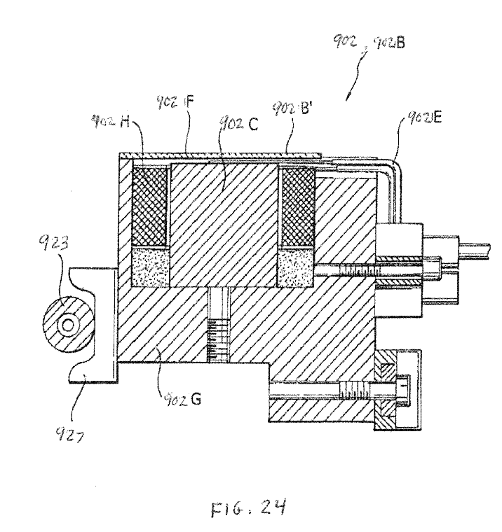

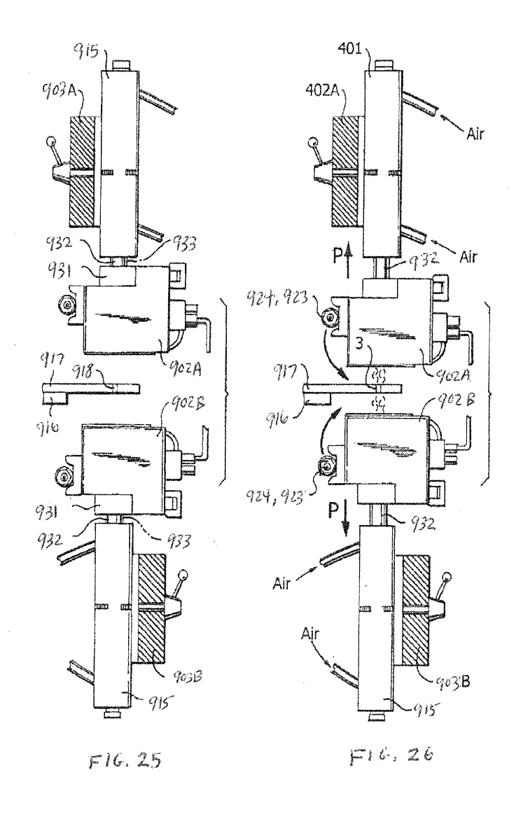

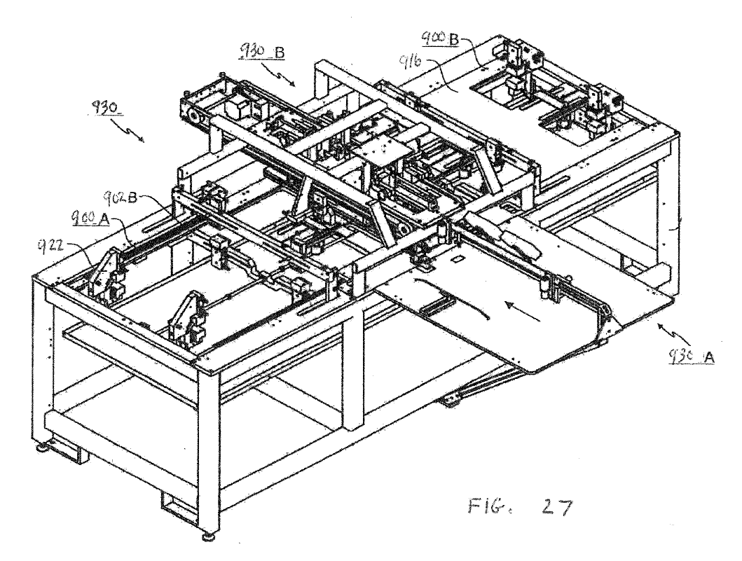

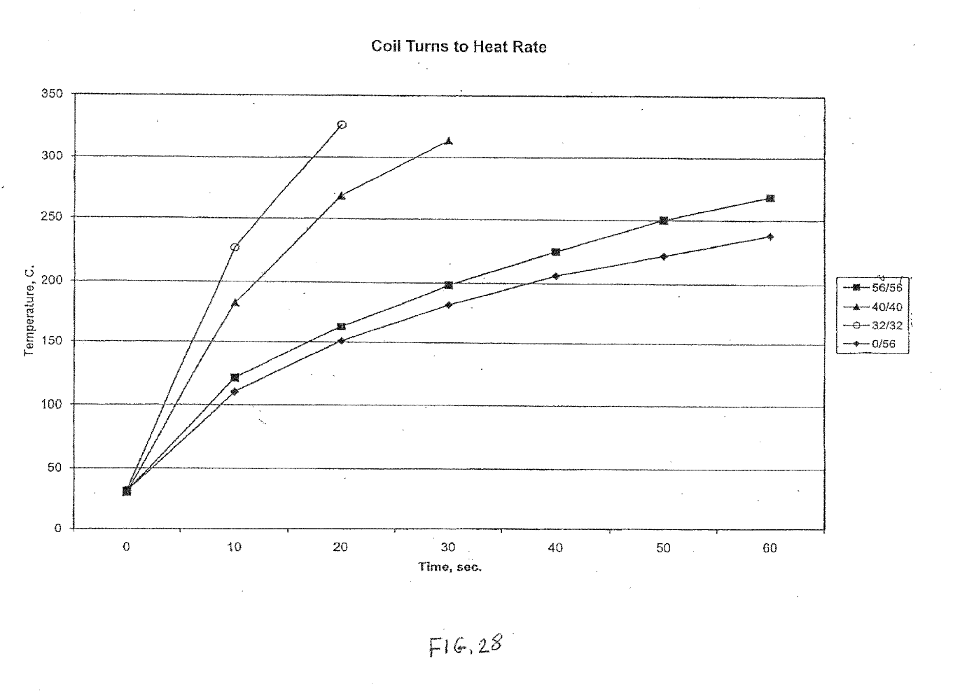

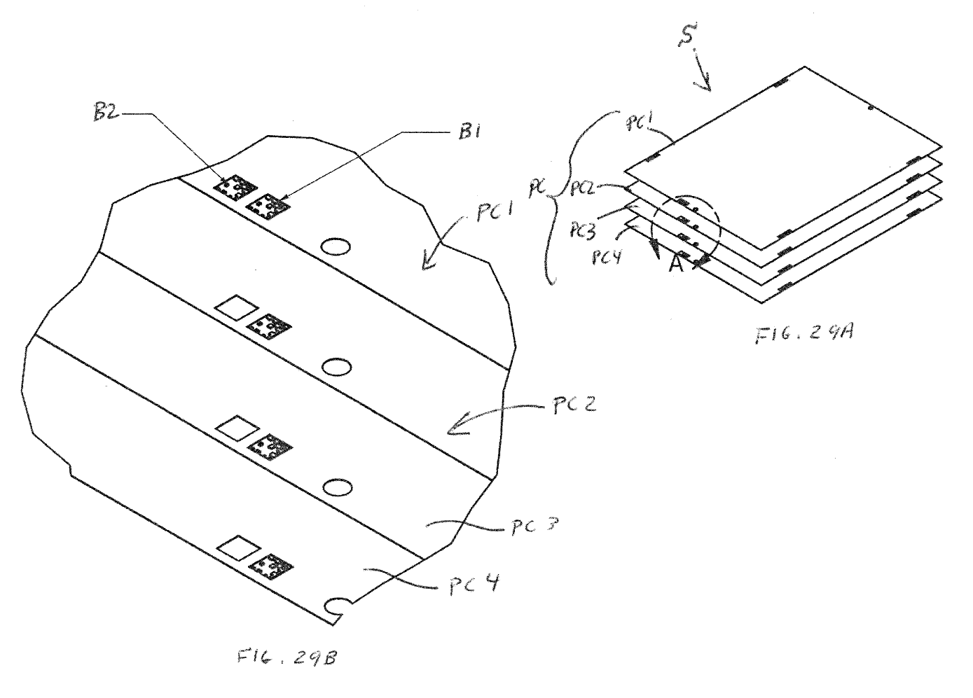

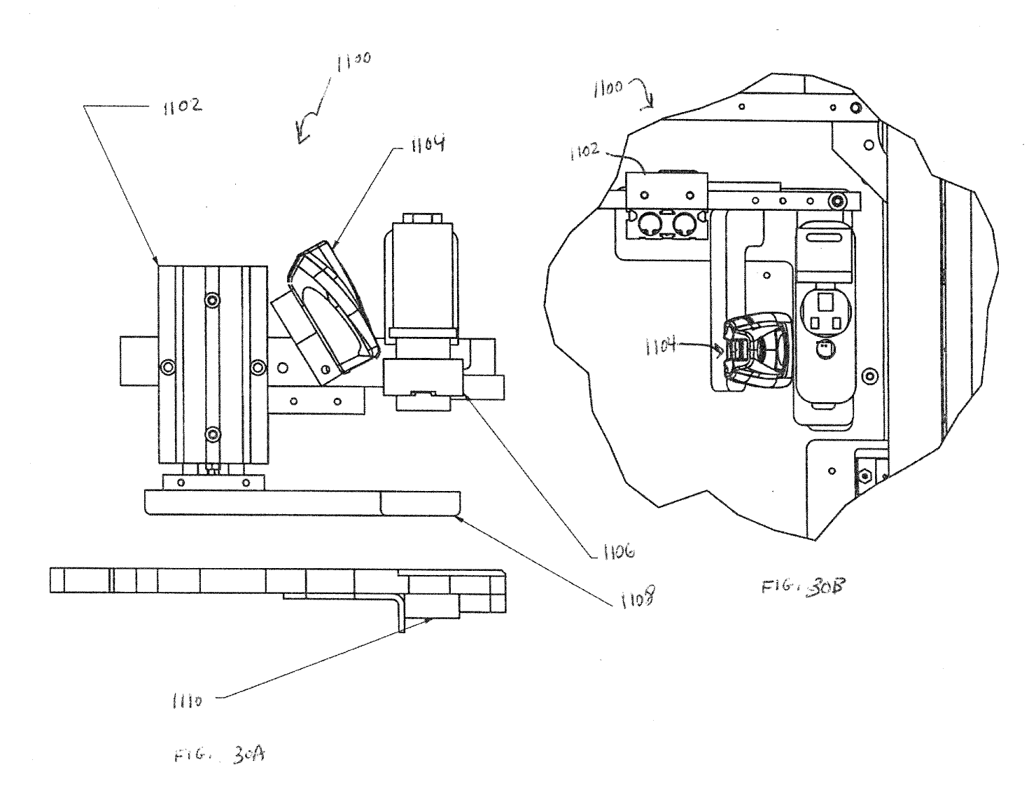

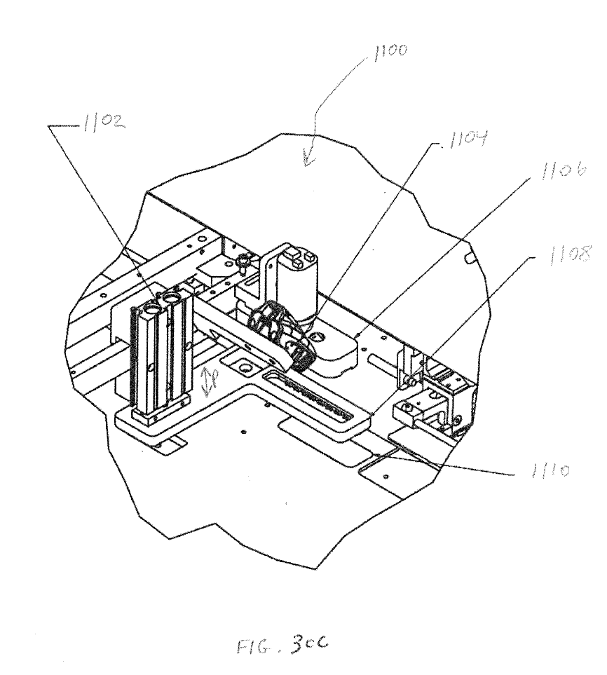

FIG. 30A is a front view of an integrated bonding station assembly in accordance with the present disclosure.

FIG. 30B is a top partial view of the integrated bonding station assembly of FIG. 30A.

FIG. 30C is a partial perspective view of the integrated bonding station assembly of FIG. 30A.

### DETAILED DESCRIPTION OF THE PREFERRED EMBODIMENTS

Reference will now be made in detail to several embodiments of the invention that are illustrated in the accompanying drawings. Wherever possible, same or similar reference numerals are used in the drawings and the description to refer to the same or like parts or steps. The drawings are in simplified form and are not to precise scale. For purposes of convenience and clarity only, directional terms, such as top, bottom, up, down, over, above, and below may be used with respect to the drawings. These and similar directional terms should not be construed to limit the scope of the invention in any manner. The words “connect,” “couple,” and similar terms with their inflectional morphemes do not necessarily denote direct and immediate connections, but also include connections through mediate elements or devices.

### A. Benefits of a Pin-less Registration System (PRS)—Initial Overview

In the presently proposed “Pin-Less Registration System,” the system combines the alignment accuracy of a CCD camera positioning system with the advantages of a bonding system. Layer to layer alignment is greatly increased by eliminating all the tooling holes and their associated tolerances. There is also no need to punch holes in the prepreg, thus this is a cleaner operation.

The layer-to-layer alignment and bonding is performed on one unit prior to lamination. This makes it possible to align internal layers and place them on lamination plates immediately. With all other tooling schemes the layers would all need to be punched or drilled before lay-up could began. Pin-less registration eliminates this extra step, and by doing so also eliminates the extra handling of the layers.

There are many advantages to pin-less registration, from handling, to speed, to improved yields, but the most important is the accuracy of layer-to-layer alignment. In order to have the best possible registered boards, its important to have the inner layers in the best possible alignment as the boards go into the lamination press. The only tooling method that can provide these results is the pin-less Registration System.

There are many advantages to pin-less registration, from handling, to speed, to improved yields, but the most important is the accuracy of layer-to-layer alignment. In order to have the best possible registered boards, its important to have the inner layers in the best possible alignment as the boards go into the lamination press. The only tooling method that can provide these results is the pin-less Registration System.

As noted a plurality of layers 90, including thinner layers 90A and standard thickness layers 90B, are provided following alignment, bonding, and lamination or drilling of a hole 93 thorough a series of copper traces 92 formed in desired regions. As can be seen there are trapped air regions between the layers (voids) occasionally, and that these regions or variations do not detrimentally impact the proposed alignment system.

As will be later discussed, the noted cross-sections in FIGS. 3A, 3B are following pin-registration, and consequently it will be recognized by those of skill in the art that the proposed system and process may be readily integrated into a review of pre-pressroom processing, book lay-up (with pins and w/o pins), and drill tooling and flash routing, thereby enabling ready integration of the proposed invention into conventional systems.

### Pre-Pressroom Processing:

As will be later discussed in detail, pin-less registration starts out by saving substantial labor and operational cycle time. Because the system relies on a proposed vision alignment system having a camera measurement station (CMS) that may also be employed for post-etch punching no additional phototool process changes are required (however, post-etch punching process is eliminated completely). Once the internal layers are aligned in the pin-less registration system (PRS) and then bonded, the bonded layers then lay up like a simple 4 layer board. This process eliminates the extra labor currently used to manually punch and align all the layers.

Referring now to FIG. 4, an graphical image of the removal of a conventional step in the proposed pin-less registration system is depicted. As will be noted, the proposed system provides a camera measurement station (CMS) including preferably ten (10) imaging cameras, as will be discussed below that then supports the additionally proposed pin-less registration (PRS) system so that in either alternative of joint use a substantial alignment benefit is provided. In contrast, the traditional registration system employs a conventional digital electronic system (DES) for tracking top-only targets on a laminate sheet and requires pin alignment.

As will be noted in FIG. 4, the proposed PRS and CMS systems enable conventional book lay-up with out alignment pins to hold bonded packages together between separator plates.

Book Lay-up of previously-bonded internal layers made using the proposed PRS system can be performed using the following two general techniques. Some presses have spring loaded corner blocks on the carrier plates to hold the assembled book in location, while others rely on the operator to center the lamination plates on the carrier sheets. Employing the proposed PRS system the process is able to align and weld internal layers without pins in a book lay-up process.

As a benefit of the provided PRS system, after the internal layers are aligned and bonded there are later book lay-up process benefits: including (1) lamination plates do not need tooling holes, (2) separator plates do not need tooling holes, (3) copper foil does not need clearances for tooling pins, (4) prepreg (resin layer) does not need clearances for tooling pins, (5) and the existing lay-up tables have two lasers for rough edge alignment providing two perpendicular lines to rapidly align the bonded package.

Referring now to FIG. 5 a representative example of the lay-up book construction without external holding pins is provided.

The following is a proposed process for laying up a book without external holding pins—for example a laying up a 10 layer board employing lamination and separator plates having no tooling holes as enabled by the present PRS system: (1) Place the lower lamination plate in position on the lay-up table and begin lay-up as usual up to the first separator plate. (2) After placing the first separator plate in location, place the untooled copper foil, this foil will be layer ten. (3) Next place the untooled prepreg, this is all the prepreg between layers 9 and 10. (4) Place the bonded package along the two perpendicular laser lines. The bonded package consists of layers 2-9 with all the associated prepreg bonded in between all the layers. (5) Place the untooled prepreg, this is all the prepreg between layers 1 and 2. (6) Place the untooled copper foil, this foil will be layer 1. (7) Place the next separator plate and repeat the process for the entire book.

Referring now to FIG. 6 a representative example of the lay-up book construction using external holding pins is provided.

The following is a proposed process for laying up a book with external holding pins—for example a laying up a 10 layer board wherein lamination and separator plates have tooling holes outside of the panel area (for example, a 18″×24″ panel using 20″×26″ lamination and separator plates with pins at the 20″ and 26″ locations). This technique uses lamination pins to hold the top and bottom lamination plates and separators in alignment to each other: (1) Place the lower lamination plate in position on the lay-up table and begin lay-up as usual up to the first separator plate. (2) After placing the first separator plate in location, insert the holding pins. (3) Pace the untooled copper foil, this foil will be layer ten. (4) Next place the untooled prepreg, this is all the prepreg between layers 9 and 10. (5) Place the bonded package along the two perpendicular laser lines. The bonded package consists of layers 2-9 with all the associated prepreg bonded in between all the layers. (6) Place the untooled prepreg, this is all the prepreg between layers 1 and 2. (7) Place the untooled copper foil, this foil will be layer 1. (8) Place the next separator plate and repeat the process for the entire book.

Following lay-up, drill tooling and flash routing are commonly conducted. In drill tooling, the tooling holes for drilling are placed by an x-ray drill tooling system known to those skilled in the art. These drill tooling machines are typically capable of drilling four holes. Two holes are ⅛″ diameter on or close to centerline for drill tooling and two holes are used for flash routing and orientation. In flash routing, the two holes for routing are ½″ away from the drill tooling holes. These additional holes are ⅛″ and 3/16″ diameter and are for orientation and for pinning on the flash router. This technique ensures that the drill tooling holes will not be damaged prior to drilling.

As a consequence of the proposed pin-less registration system for providing aligned and bonded packages to the lay-up process a number of advantages and cost savings are realized. These include but are not limited to: Flexibility utilizing lamination plates; Plates do not need tooling holes, this allows the plates to be used for multiple panel sizes, and thus fewer sets of lamination plates are needed; Separator plates also do not need tooling holes this allows the plates to be used for multiple panel sizes, thus less sets of separator plates are needed; Cleaner operation, cleaning plates are easier to clean, there are no resin filled tooling holes; Copper foil does not need clearances for tooling pins, foil is easily damaged when trying to lay-up on pins, this problem in eliminated; Prepreg does not need clearances for tooling pins which this minimizes prepreg dust; There will be more flexibility in panel sizes without the restrictions of the pins; The lamination pins and bushings are eliminated, thus eliminating a consumable; and depinning is not necessary.

### B. Description of an Integrated System for Pin-Less Registration System (PRS) Operation Employing a Multi Camera Measurement Station (CMS)

What is proposed is a Pin-Less Registration System (PRS) that enables multiple inner layers to be registered together for pressing into a completed multilayered circuit board at a time desired by a manufacturer following an initial measurement by a multi camera measurement station (CMS). While the PRS system may be employed without an initial CMS system the use of a CMS system in concert with the PRS system brings enhanced performance, as will be discussed.

Referring now to FIG. 7 a perspective view of an optional multi-camera measurement station (CMS) 500 within a mechanical supporting structure (not shown) similar to that in the PRS system (discussed later) the is provided with a first top set of cameras 501A, 501B, 501C, and 501D, and a second bottom set of cameras 502A, 502B, 502C, and 502D and respective centerline reference target image units 503A, 503B arranged along a centerline between respective target points 401A, 401B for later interlayer alignment from a pre-set position of a first alignment layer 105. As will be recognized by referencing the figure, top set of cameras 501A-D and bottom set of cameras 502A-D image respective top targets 402A-D, and 402E-G on layer 105. Collectively the imagery or alignment data generated by the CMS system is commonly referred to as a first reference orientation data set for the particular sheet. Thereafter the first reference orientation data set may be pushed through various algorithms to determine best fit and other details relevant to a desired alignment, the centerline, or other standards as may be determined by a customer. Ultimately, following the generation of a group of first reference orientation data sets for respective sheets 105, and the calculation (to be discussed), a preferred stack orientation may be calculated for a combination of the multiple laminate sheets optimized employing the first reference orientation data set.

As noted earlier, the pin-less registration system (PRS) provides for pin-less lamination of multilayers and sequential lamination build up technology. Consequently, the PRS approach utilizes machine vision technology to pre-align layers during lay-up (discussed above) and then bonds the internal book together, securing the alignment during the press cycle. To optimize the PRS system it is preferred (but not required) to employ the CMS system for processing multiple layers prior to later assembly at the PRS station. As will be discussed later, the PRS utilizes two cameras on centerline for inner layer alignment, and due to the lay-up process it would not be achievable to align the layers to top and/or bottom targets in the alignment station. Consequently the CMS measurement station employs a total of at least ten (10) imaging cameras to determine overall fit and an initial centerline alignment for later reference.

The addition of a Measurement Station allows for either positioning to “the more critical layer” or “split-the-difference from top to bottom” allowing a user to determine which process best fits the manufacturing need.

The best-fit location is calculated based on a reading of all cameras and is within the computer control system referenced to the two top centerline reference targets 915A, 915B for later positioning in the PRS system. In effect the computer control system for the CMS and PRS systems cooperate to calculate the offset of the top centerline targets to the best fit position of the remaining 8 alignment targets on the outer corners of each sheet shown as 903A, B, C, D, E, F, G, and H (4 targets on top, 4 targets on the bottom). As was earlier discussed, a pre-alignment station may be used to augment the process still further.

In the proposed system, each respective layer to be aligned is first placed in the measurement station (CMS) so that the targets are in the field of view of the cameras. The Measurement Station images the layer and employing electronic computational analysis obtains both the initial orientation data set and the calculated the best fit position and checks target tolerance criteria of top and bottom targets at positions 402A-402H. Additionally, the measurement station now calculates the relative position of the two top targets to the best fit position and sends the data to a database for later reference by the PRS alignment station. It shall be recognized that the proposed storage database may be within the PRS alignment station (to be discussed), or elsewhere for example within a centralized management computer system (server) accessible by the CMS and PRS systems without departing from the spirit and scope of the present invention.

Following all necessary measurements, layer 105 is physically transferred to either longer-term storage for later use or the to-be discussed PRS for lay-up, at this point the PRS utilizes the best positional data calculated for that layer by the Measurement Station, and aligns the layer (as will be discussed.) The CMS measurement process is then repeated for all layers and after assembly at the PRS lay-up is completed the bonding cycle takes place.

Referring now to FIGS. 8 through FIG. 19B, a pin-less registration system (PRS) 400 is discussed. The PRS 400 system uses a machine-vision system, which locates fiducial targets, in conjunction with an X-Y-Y positioning table to manipulate each inner layer to a predefined location, where a system of clamps holds the layer in place (as will be discussed).

Generally, during operation (as will also be described in a sequence-of-operation below), each successive layer (previously imaged by the CMS) of the to-be-created multilayered circuit board is loaded into the PRS machine, along with a sheet of pre-preg (resin sheet) insulating material, via a gripping loader system, where it is positioned and clamped. When all of the inner layers are positioned, a set of welding heads is engaged. The heads spot-weld the inner layers and pre-preg together forming a securely joined panel.

When the welding process is complete, the gripping loader system (to be disclosed) is used to eject the completed panel to an external unloading device.

As constructed, the controlling computer system for the PRS performs various Statistical Process Control checks to ensure that the layers are within inputted allotted positional and material tolerances employing selected algorithms. In a preferred embodiment, the system makes use of a touch-screen monitor to provide the main user interface in a convenient manner. The system is controlled and configured via the touch-screen interface. When necessary, a virtual keypad is displayed on the screen, allowing for the entry of set points and configuration information, or the retrieval of previously stored (on a network server for example) initial data regarding a particular layer 105.

### General System Description:

The PRS Pin-less Registration System is comprised of the following major components outlined below:

Compatible computer or computer control system or systems such as a server-centralized system, which runs a dedicated, custom control application, which provides the operational functionality and user interface described herein—including movement control and data management.

Touch-screen monitor (preferably operating as an input interface) that provides a means of displaying a custom designed user interface, and allowing for easy operator interaction at a manufacturing location, including (optionally) a virtual keypad used to enter set points and configuration and other data.

Machine Vision Cameras (as discussed) that provides images of the fiducial targets. A vision Processing Algorithms may be housed within the compatible computer or computer systems. These processing programs enable configurable, trainable algorithms that provide the method for locating the fiducial targets in the field of view of the cameras. The algorithms are configurable for multiple shape, size, and search acceptance criteria.

A Motion System may provide: the means for mechanical and electrical material input and output from the machine, the means of operational sheet manipulation inside the PRS machine, such that the layers are moved to predefined and controllable positions, and a configuration of the machine to the material based on the panel size input via the touch-screen interface.

A Spot Welding System may provides the means of holding the layers together for further processing outside of the PRS, for example an induction bonding head may be employed as a spot welding system.

A Machine I/O System may provide the electromechanical (pneumatic, hydraulic, electronic, mechanical, sensor) means for controlling the grippers, clamps, platen, etc. and may include both outputs to devices, and inputs from various sensors.

Generally, during “Machine Operation,” once the system is powered up and the PRS software controller application initialized, the system is ready for operator interaction. In practice, the operator employs a “Job Setup” interface screen to describe the customer-defined job parameters (including, for example, how many layers are to be positioned per panel, the “X” Panel Size (for example 18″×22″), particular Weld Head operation parameters, and whether SPC or other analysis will be utilized).

Once the Setup information is complete, the operator initializes the PRS system 400 for operation. This is done via additional buttons on the User Interface. The system initializes all axes of motion, and moves the cameras to the designated X Panel Size. The Platen, Clamps and Gripper system are similarly configured for operation.

As will be later discussed in detail, an operator places the first inner layer 105 to be positioned on the loading station. A set of cameras and monitors in the operator loading station are used to facilitate pre-positioning with relation to the grippers and tooling inside the machine. When the operator is ready, a start button is actuated. The mechanical grippers grab the layer, and drag it into the machine, placing the layer at the proper computed position, based on the input X Panel Size, so that the fiducial targets are visible within the field of view of the multiple cameras inside the machine.

Once inside, the platen system is engaged to grip the layer from above. A vacuum generator holds the layer, while a sub-platen is used to lift the layer above the base plate and any other clamped layers. A multi-camera measurement system within PRS machine 400 analyzes the target fiducials from within the camera fields of view, and computes any additional correcting manipulation moves (to achieve for example a best fit). The X-Y-Y table is used to position the inner layer accordingly. The vision system is re-checked for positional accuracy. The sub-platen places the layer firmly on top of the base plate or pile of clamped layers between each move. If the layer is within the configurable positioning tolerance, the layer is clamped, the platen raised, and the system is ready for the next layer. While the layer was being positioned, the loading grippers are returned to the load position, to be ready for the next layer.

When all layers have been positioned and clamped, the weld heads are engaged, for a configurable time profile, to secure layers 105 together. Once complete, the loading grippers are used to eject the completed panel from the PRS system 400 and the process begins again.

During processing, the vision system is used to ensure that the fiducial targets are the right type, size, and orientation. Statistical Process Control computations are performed on each layer, relative to the first, to show relative expansion/contraction of each successive layer.

Referring directly now to FIGS. 8 and 9, a pin-less registration system 400 is provided with a pre-alignment or measurement station 400′ extending external to an inner imagery and positioning system as will be discussed. Pre-alignment station 400′ may also be referred to as an operator loading station, and includes supporting loading table 131, braced by loading table support 135 to provide a stable platform for receiving typical layer 105 below a camera slide 132 supported by an end bracket 134, as shown.

Typical layer 105 includes central reference targets 401A, 401B (as earlier discussed and not shown) for viewing by two lateral CCD cameras 133, 133 positioned on camera slide 132. A LCD pair of load monitors 136, 136 provides visual feed-back to operators for pre-aligning typical layer 105 relative to respective targets 401A, 401B. Following pre-alignment load gripper assemblies 104, 104 operate relative to a front work plate 108 for the PRS device 400 to grip layer 105 following initial operator alignment and data entry and retract (to the right in the views) it into the PRS machine in an aligned and re-set manner depending upon pre-alignment data readings via CCD cameras 133, 133.

It is procedurally envisioned, that operators employing pre-alignment station 400 follow the following process: (1) Operator inserts inner layer 105 for a first layer into the Pre-Alignment Station 400′. (2) Target are in the field of view of the Pre-Align CCD cameras 133, 133 as determined by inspecting images on screens 136, 136. (3) Operators presses start button (not shown) of the automating loading and alignment system. (4) The two loading grippers grab the layer and raise it for movement (approximately 20 cm). (5) The layer is now pulled into the PRS positioning system 400 and placed in the field of view of the main positioning cameras arrayed in a manner similarly discussed in the computer measurement system (CMS) or in another manner effective to achieve the benefits of the proposed invention. (6) The load grippers return to the load position as the PRS begins the alignment. (7) The operator inserts the next layer and the prepreg sheet. (8) Steps 2 to 7 are repeated for all layers in that panel. (9) Once the last layer is aligned, the panel is welded/bonded. (10) After the bond cycle, the second set of unload grippers grab the bonded panel and send it out of the machine. (11) During step 9-10 the operator repeats step 1-3. (12) Once step 10 has completed the machine will repeat steps 4-10.

A slightly modified and alternative process is noted as follows and includes the earlier discussed CMS system for enhanced accuracy: (1) Operator inserts a defined inner layer for first layers into the Measurement Station of the CMS. (2) The Measurement Station calculates a best fit position and electronically transfers the data to the PRS alignment station or other controlling computer system. (3) The operator now physically moves the layer into the PRS positioning work area. (4) The PRS alignment station 400′ of PRS 400 aligns layer 105 to the calculated best fit position via machine vision technology and multiple axis movement (as will be discussed). Two cameras are used to detect the two centerline top targets. (5) The inner layer is aligned and held in place by two sets of edge grippers. (6) The center vacuum platform is raised and the next inner layer with the associated sheets of prepreg is introduced into the work area. (7) The vacuum platform is lowered onto the inner layer, thus completely flattening the inner layer. (8) Vacuum is then activated and the platform raises less than 0.015″, the CCD or CMS similar 4-10 camera system digitize the earlier identified targets and a positioning system moves the inner layer to the optimally aligned position. For example an initial sheet may employ a bottom or other view while following sheets may commonly employ only a top view (4 camera view). (9) The platform is lowered and the vision system rechecks the alignment, the grippers release and regrip, the grippers now hold both inner layers with the prepreg sandwiched between them. (10) Steps 4 through 7 are repeated for the successive inner layers for a given panel. (11) When the lay-up is completed, the bond cycle is activated and the layers are held in position at six bonding locations. The operator removes the bonded package and begins the next lay-up. (12) The bonded package is processed in the multilayer press without pins as a four layer PCB.

While non-limiting to the present disclosure, the following are proposed specifications for a potential PRS system.
Positioning System Repeatability: ⁺/− 17 micron- ⁺/− 0.7 mils. (Checked with dial indicator on positioned panel)
Panel sizes: Min 300×455 mm (16″×18″), Max 610×760 mm (24″×30″)
Panel alignment speed: 7 seconds/layer average (dependent on target quality and operator pre-alignment speed)
Positioning system: X-Y-Y axis, cam driven, closed loop system thru CCD cameras
Bonding Type: Inductive (preferably)
Bonding panel thickness: Greater than CCD depth of field
Target size diameter (suggested): 0.75 mm-1.5 mm (0.030″-0.060″)
Vision System
   Types of cameras: Synchronized Image CCD elements
   Depth of field: 8 mm (0.320″) but not limited thereto
Illumination: UV LED ring lamps
Inner layer Copper type: No limitation
Pre-preg type: No limitation

Thus, those of skill in the operational and system arts should recognize the following highlights of the proposed system operation.

The PRS system 400 uses the results of Vision Processing Algorithms to determine the current position of an inserted layer 105. That position is calculated, in relation to a pre-defined X-Y location within the machine, relative to the welding heads (not shown). The difference is computed in terms of X, Y1, and Y2 moves, and used as input for the motion and gripping systems (to be discussed).

The weld heads are configured to operate at individually set temperatures. The heads are active, but idle, until the proper time for welding. At that time, the heads are brought to the configured temperatures, and engaged to weld the layers together. At a configured time, the heads return to the idle state, and a series of air cooling jets are used to cool the heads and the spot welds, and the completed panel is ejected from the system.

In reviewing the above, those of skill in the art should recognize:

The vision system analyzes the target fiducials from within the camera fields of view in manners known to those of skill in the imaging arts. Here, the system performs a grayscale search for a trained image. This search is tolerant of defects in the target and variations in lighting and contrast. The search returns results of score, scaling, rotation, and position (X, Y).

The results from each camera are validated based on a readily configurable limits (for score and scaling). The positions (X & Y) are then processed with the following computations:
The X & Y coordinates of each fiducial target are computed in relation to a set of X & Y configurable Reference Positions. The error is computed in X and Y.
The errors for each camera are related to moves that we can make using the X-Y-Y table. In this case, the X errors are averaged (since any X move moves the entire panel in X, any move made will affect both sides). The Y errors are handled independently, since the system can move the left and right sides independently.
A final set of X, Y1 and Y2 moves are computed, based on the configurable entries of camera Pixels Per Mil, and Motor Steps per Mil. In addition, a computation of this layer's spread (expansion or contraction) in relation to the first layer positioned is computed. If this is the first layer, the spread is (by definition) 0.

A decision is made as to whether the layer is within the configurable positioning tolerance (X, Y1, and Y2) or not. If the layer is not in position, it requires a move and raises a preferred decision operator flag. Note that the system will only make up to a configurable limit of moves before aborting the positioning procedure under the present programming.

The Sub Platen is raised, holding the top layer via a vacuum lock.

The X-Y-Y table is moved based on the corrective moves computed above.

The Sub-Platen is lowered, but still holds the layer via the vacuum lock.

The vision system again analyzes the target fiducials, and the process begins again.

Once the layer is in position:
If the system is configured to utilize the spread computation, the layer's spread is compared to the configurable limit. If the layer is within tolerance, it is gripped via the clamping mechanism. The layer is held in place so that the next layer can be loaded on top and manipulated without affecting the stack up of layers already in the machine.
If the layer is out of tolerance, the operator is given the choice as to whether to reject this layer or to clamp it anyway. If this layer is rejected, it is manually removed from the machine, and the system is then ready for the next layer to be loaded. The rejected layer does not count towards the number of layers required for the final stack up.
If the spread tolerance enforcement option is disabled, the layer is always clamped.

Once all of the required layers are present, positioned, and clamped, the system begins the bonding process.

The weld heads are engaged, and come up to the configured temperature profiles.

The weld heads are allowed to operate for a configurable time profile, to secure the layers together.

When the weld time is complete, the heads are deactivated. A set of air cooling jets is utilized to cool the material for a configurable time.

Once complete, the heads are disengaged, and the loading grippers are used to eject the completed panel from the system.

As noted above, the common “sequence of operation” is as discussed in the following steps:

1. The operator places the first layer in the machines work area with the two alignment targets in the field of view of the two cameras, and presses the start button.

2. The alignment/vacuum platform is lowered on top of the layer, this completely flattens the layer thus ensuring correct positional calculation of the center-to-center distance of the targets.

3. The unit aligns the layer to a preset zero position via machine vision technology and multiple axis movement. (“X”, “Y1” “Y2” and “Z” axis)

4. Once in position, the layer is held in place by two sets of edge clamps.

5. The alignment/vacuum platform is raised and the next layer with the associated sheets of prepreg is introduced into the work area.

6. The alignment/vacuum platform is lowered onto the layer, thus completely flattening the layer.

7. The unit aligns the layer to a preset zero position via machine vision technology and multiple axis movement. (“X”, “Y1” “Y2” and “Z” axis)

8. Once in position, the first aligned layer, prepreg and second aligned layer are held in position by the alignment/vacuum platform.

9. The clamps release the first layer, move out of position and then re-clamp, the clamps now hold both layers with the prepreg sandwiched between them.

10. The vision system rechecks the alignment of the top layer and then the alignment/vacuum platform is raised for the next layer and prepreg to be aligned.

11. Steps 5 through 10 are repeated for the successive layers for a given multilayer panel.

12. When the lay-up is completed, the bond cycle is activated and the layers are held in position at the bonding locations.

13. The operator removes the bonded package and begins the next lay-up.

This process eliminates all tooling hole and lay-up tolerances and optically aligns all layers to either top, bottom or both sets of targets. As noted earlier, the PRS system enables the following benefits:
Elimination punched or drilled holes, this is more accurate because it also eliminates all the hole tolerances
Align layers to most critical layer, may be the bottom layer
Align to best fit position of top/bottom of layer
Align sub-assemblies to via or drilled holes
Improved layer-to-layer registration through PC based machine vision capability.
Elimination of post-etch punch process steps and associated labor.
Maximum process flexibility by eliminating panel-size specific tooling.
Automatic and semi-automatic versions available.
Small footprint as compared to post-etch punch.
Improved X-ray drill performance.

Referring directly now to FIGS. 10 to 19B, an alignment and assembly table system 600 includes multiple X-Y-Y bearings 1 positioned relative to a vacuum plate 2 enabling operation of a series of cam followers 3.

A lift plate 4 supports the same and shaft clamps 5 secure vertical shafts 6 for vertical motion. Respective securing brackets 7 secure mounts 8 for engaging stepping motors 9 to operate system 600. Computer controlled vacuum manifolds 10 enable gripping of sheets 105 during operation. A bracket sub-platen sensor 11 enables reliable sensing during movement. Cams 12, operable with cam shaft springs 13 enable secure adjustment as will be explained.

A series of sensors including proximate sensor 14, actuator and sensor set 15, and panel sensor 16 enable secure computer control of system 600 and enable a managing computer system to determine precise location of all movement within system 600 of PRS system 400.

As is visually noted there are preferably at least four bearing assemblies 1 provided for multi-axis adjustment, although other configurations are contemplated. There is also a plurality of control-ably driven stepper motors 9 for rapid adjustment as shown.

Referring now to FIGS. 17, 17A, a bearing assembly 800 containing bearing member 1 is provided with an air cylinder 1′, a pair of slide bearing 2′ and bearing plates 3′ (fixed) and 4′ (movable). A stroke adjuster 5′ is provided for adjustable operation there between and a threaded member 6′ fixed by a nut 7′ secures a washer 8′ and lock washer 10′ relative to stroke adjuster 5′ to secure an adjusted operation bearing position. An end member 9′ secures bearing plates 3′, 4′ respectively.

Referring now to FIGS. 18A, 18B, bearing assembly 850 (like bearing assembly 800) for an X, Y, and Z slide member is provided in a simplified manner in support of the above disclosure. As noted an air cylinder 1″ positioned relative to a set of slide bearings 2″, 2″ and a set of bearing plates 3″ (top) and 4″ (bottom) and enables adjustable motion of movable plate 4″ relative to slide bearings 2″. A stroke adjuster 5″ and screw 6″, nut 7″, lock washer 10″ enable operative adjustment understood by those of skill in the art. As disclosed movable bearing plate 4″ is mounted to the vacuum plate discussed above for smooth and secure adjustment. A locking member 9″ secures bearing plates.

Referring now to FIGS. 19A, 19B, a cam positioning system 851, discloses a vacuum plate 2x movable (as shown) relative to cam follower 3x and plate lifter 4x. A bracket 7x for holding a positioning motor 9x (stepper motor) enables operation. A mount 8x secures positioning motor 9x, and a positioning cam 12x and cam spring (not shown) enable camable operation and motion control of vacuum plate 2x tracked by a proximity sensor 14x.

Referring now to FIG. 20 through FIG. 21D, an integrated bonding station assembly 900 is proposed and includes a plurality of bond head assemblies 901 depicted respectively as top and bottom bond head assemblies 901A, 901B. A support frame assembly 903′ includes a plurality of horizontal support bars 903, 903 joined by an adjustable positioning system 904 including respective sliding shaft members 904A, 904A with sliding bearing blocks 904B and locking pins 904C in blocks 904B for fixing a final adjusted position during a set-up or an assembly depending upon a manufacturer's requirements. A top horizontal support bar 903A extends from vertical support members 403, 403 fixed to respective ends of one of the horizontal support bars 903, as shown. A plurality of slidable adjustment slots 903B are positioned along respective sections of horizontal support bars 903, 903, 903A, as shown.

During manual set-up (as shown) or during an optional automated adjustment, a threaded drive shaft 904D threadably drives and engages a threaded drive bearing portion 904F of one of the horizontal support bars 903, 903, 903A and allows an operator to maintain a parallel position between respective horizontal support bars while adjusting laterally via sliding shafts 904A, 904A until a final bond-head position is achieved. While not shown, those of skill in the mechanical, electrical, and computer control arts, having studied the present discussion, shall recognize that threaded drive shaft 904D is supported by a driving motor, linear accelerator, or other motive means (all not shown) to allow horizontal motion as desired within the scope of the present invention, and that this motion and adjustment may be readily automated.

A threaded locking member 904E extends through respective slidable slots 903B and enables securing respective bonding heads 901A, 901B as desired relative to an inter-positioned layer 1 (FIG. 21) having respective defined bonding regions, either along an edges of a sheet, or as allowed by the present construction within the non-edge field of the sheet.

As will be noted in FIG. 20, the left-top side bond head sets 901A, 901B are slidably fixed to mounting block assemblies 914, 914. Mounting block assemblies 914, 914 are slidably adjustable along slots 903B, 903B and securable vial locking levers 904E, 904E in a manner similar to the independently mounted bonding assembly side of bonding station assembly 900. As shown, when mounting block assemblies 914, 914 are employed, respective bottom bonding assemblies' 901B in fixed, non-movable positions, although as will be recognized easy modification allows automated movement. Mounting block assemblies 914, 914 also include at a top or upper portion air cylinder unit members 915, 915 that extending air-cylinder arms fixed to top bonding heads 901A, 901A so as to allow relative vertical movement of respective top bonding heads 901A, as will be explained.

As will also be noted in FIG. 20 (and FIGS. 25 and 26), the right-bottom-side bond head sets 901A, 901B are slidably mounted to horizontal support bars 903, 903A via respective air cylinder unit members 915, 915 so as to allow vertical movement of each bond head 901A, 901B independent of each other during a use. As will be additionally appreciated, because respective bond heads 901A, 901B are operationally independent (each can create an induced field alone without mechanically joining or coupling to the other bond head portion as required in the related art), they may be split apart, and sheet members 1 may be slid between each bond head assembly 901A, 901B during stack assembly for enhanced positioning ease.

As a consequence, and as will be discussed in FIG. 27, the present construction supports the use of multiple bonding stations receiving fed sheet-lay-ups for eased and enhanced production rates.

As will also be appreciated from considering the present invention and FIG. 20, driving shaft 904D (with bearing 904F and the driving motor (not shown)) may readily position and reposition the horizontal support bars 903A, 903 along the entire field of sheet 917 by sliding along sliding shafts 904A, thereby allowing bonding within the greater field (between the edges) of the stack of respective sheets 917 to be bonded.

As will be appreciated, the present assembly in FIG. 20 is shown allowing for simple horizontal (left-right motion) along sliding shafts 904A (X-direction) and simple vertical (Y-direction) motion along slots 903B, whereby ready repositioning and adjustment is achievable. However, the present invention is not limited to this construction and it is specifically contemplated herein that linear accelerators, linear motors, drivers, and other automated accurate positioning devices (all not shown) may be joined to respective bond head assemblies 901A, 901B and respective air cylinder units 915 so as to move the same along respective support bars 903, 903A and sliding shafts 904A, 904A so as to be able to bond in any region of the entire field of stacked sheets 917, upon a computer control (not shown) or a mechanical control (shown via positioning locking pins 904E and other mechanisms allowing full X and Y direction movement relative to support plate 916.

As a consequence of the present construction and description, those of skill in the art will readily recognize that the present invention enables bonding to occur throughout the entire area of sheet 917. As a consequence, since at least one set of horizontal supports 903, 903A are split (not fixed to each other) they may move relative to a support plate 916 over the stack of sheets 917, may extend from one side or another, or may be independently supported allowing complete bonding motion.

As a consequence, it will be recognized following review of this description that the presently proposed solid copper pads 914 (FIGS. 21-21D) may be positioned anywhere within the sheet 917, commonly within target identifiers 919 (shown as a target ring for optical recognition), allowing for the use of and the secure fixing of sub-assembly stacks during lay-up (for example, a larger sheet (and stack of sheets) may be designed to contain a plurality of smaller integrated circuit designs that may be bonded close to their respective boarders within the larger sheet field for enhanced reliability and so as to prevent shifting during transport to later bonding stages.

Thus, while the presently preferred configuration employs a mix of split bonding head units and movement systems, alternative combinations and configurations may be provided without departing from the scope of the present disclosure and will allowing for motion of the bonding heads in three directions (X, Y, and Z), as well as the use of individual or singular bonding head (single side bonding) assemblies.

Referring now specifically to FIGS. 21, 21A, 21B, 21C, and 21D, the present discussion notes the use of differently shaped solid copper pads 914, 918A, 918B, 918C, and 918D, or optionally a series of concentric rings 918A′, 918A″ and a copper pad 918A centered therein. It is noted that each copper pad shown is continuous in its central region but the shapes are not limited to the ones shown, and may be employed as any regular or irregular copper pad. The copper pad acts as an improved heat source during induction on every layer and provides a unified and homogenous bonding thermal (heat) supply region to improve bonding reliability through multiple stack layers. The concentric rings 918A′, 918A″ do not generate heat (typically they are too far from the thermal concentration although they will induct/heat if sufficiently close), they act as constraints (dams) for the bonding resin that will flow during bonding and then cure in place. Thus, the concentric rings are not in short circuit, they do not connect to each other or the central copper pad, but they do provide an improved quality of bonding by containing resin during bonding and improving quality control.

Pad types, sizes and dimensions can vary according to the customer's border area design, or to the available area on the inner layers within a multiplayer construct. For example, a copper pad may be shaped as a large “L” allowing for easy corner bonding of a sub-assembly within a larger sheet. Alternatively, a copper pad member may extend in some way beyond the normal diameter of the center of the bonding head, and employing the present invention it is contemplated that the bonding heads may be driven along the copper pad member according to a desired bonding rate to secure the entire bonding pad area. The customer can also choose to etch the concentric rings if space allows so that the etchings will similarly serve as a resin dam mechanism to contain the melting/fluid resin during bonding.

Specifically referring now to FIG. 21, bond head mounting block 914 is slidably positioned along a slid-adjustment direction S relative to adjustment slot 903B on horizontal support rail or bar 903, as shown. A terminal mounting block 926 is fixed to block 914 and receives electrical power and thermal couple wires serving to bonding head assembly 901A, as will be discussed. Top bonding head assembly 901A is positioned to a movable plate 931 joined with extending air cylinders (shown later) extending from air cylinder unit 915 supplied with controlled air supply 915A via a plurality of hoses and joints as shown. As a consequence of this construction, it will be recognized that top bonding head assembly is readily movable in the vertical position P relative to support plate 4, sheet 917 (or a stack of sheets 917) positioned between respective bonding heads, and bottom bonding head 901B.

Bottom bonding head assembly 901B is shown fixably mounted to a bottom portion of mounting block 914, and is covered with a cover plate member 901B′ as will be discussed in further detail. For example, cover plate member 901B may be a ceramic (here alumina, SiO2, Zircon, etc.), a metal, a fiberglass, a polymeric material, or a multiple layer construction that is sufficient to resist thermal degradation eliminate adhesion from spilled resin during use and deformation under pressure. For example, this construction keeps any resin that may flow out of the bonding area of the panel from adhering to the coil and ferrite core. Here the alumina is a very hard non-stick surface; so that any resin that flows onto it will be easily removed with a razor blade type scraper after cooling.

Included on each respective top and bottom bonding head assembly 901A, 901B is a cooling system 300, shown here as an air cooling system with an air supply feed 301, but nothing herein shall so limit the disclosure. For example, cooling system 300 may include radiant cooling fins extending from each head assembly, internal liquid or air-cooling systems, and multiple-location cooling systems. It shall be recognized that cooling system 300 aids and speeds thermal cycling by providing a cooling effect to both respective bond head assemblies, but also optionally to respective bonded sheets, and bonding sites, etc. Thus, cooling systems 300 improve rapid cycle time, reduce required time-between-bondings and improves quality by rapidly cooling the bonding site during sheet with drawl from the bonding position and movement between positions.

Referring now to FIGS. 22-24, a bonding head assembly 901 is shown, here oriented as a bottom bonding head assembly 901B, although both top and bottom assemblies are similarly constructed (terminal block members 926 are differently positioned as noted in the figures). A core block member 901G is formed as a generally rectilear body and includes an inner cavity having a flat bottom for receiving an E-shaped or 3-legged ferrite core element 901C and a wound core 901D having an extending core power supply 901E for supply electrical current. A thermocouple 901F, is formed having a reasonably thin film or foil member at its end so as to lie flat on the top of the central leg of the E of the ferrite core 901C and allow cover late 901B to be positioned to cover the entire assembly in a flat manner. Since thermal couple 901F is so thin (no more than 1/16^{th} of an inch), there is no detriment or stress concentration on the center of the E of the ferrite core so that maximum assembly temperature is accurate (central location of the thermal couple for improved temperature reliability) and simple (a simple positioning is required), and simple replacement is enables by merely removing cover plate 901B. After such assembly, a bonding epoxy 901H (commonly thermal carbon black) is used to fill in any remaining voids and lock the assembled ferrite core and core into core block 901G. It will be recognized that different bonding epoxy compositions may be used to fill and secure the assembly without departing from the scope and spirit of the present invention.

Respective thermal couple lead wires and power supply wires to the wound core are joined to terminal block 926 secured to mounting core block 901G by a mounting bracket 926a (in block 901B) or on a mounting block 914 side for top bond head assembly 901A (see FIG. 21). Cooling mount brackets 927 secure cooling system 928 in position and allow for the easy direction of cooling air at the hot bond head and the bonded sheet stack for reduced cycle time.

As will be appreciated by those of skill in the art having read and understood the present disclosure, due to the shape of E-ferrite cores the center-leg of the E serves to both concentrate the induced field for enhanced bonding and to provide strong central support for the bonding stack during the bonding step. As a consequence, while thermal couple 901F is preferably positioned (as shown) as close to the center of the induced field leg as possible, alternative thermal couple positions may be employed without departing from the scope and spirit of the present invention. For example, a thermal couple may be placed near the top of core 901D between the legs of the E-ferrite core for assembly convenience. As noted, the proposed system has an imbedded thermocouple probe that measures the temperature of the coil, thus allowing for a predictable curve of for a controlling temperature ramp rate and voltage supply. It will be similarly recognized that alternatively dimensioned E-shaped ferrite cores may be employed without departing from the scope of the present invention.

In practice, cooling system 928 may be (a) continuously activated, (b) activated upon reaching a temperature set point (determined by a locally set thermal couple on/in the bond head or proximate to the bond head or stack of sheets 917), or (c) preferably activated after the heat temp/bond cycle has completed and works sufficiently quickly to accomplish cooling between cycles by supplying clean filtered air for temperature maintenance.

As also suggested the present system provides for a computer control mechanism enables individual control of a heating ramp rate, hold time and cooling time and power supply as will be discussed.

As will also be recognized by those of skill in the art having view the entire disclosure, the use of E-shaped cores enables the use of 100% of the magnetic field for each head during bonding, with approximately 50% of the induced field cycling through each outer side of the “E” and returning to the thicker central “E” portion, and with 100% of the field centered in the bonding head contact surface. As a consequence, the present invention provides at least twice (2×) the width of a conventional induction coupling area than that available in the related art noted above. As an additional benefit, where two inductive heads are used in vertical cooperation the magnetic fields from each E-core join faulting a very wide inductive field and need only extend a portion of the way through a sheet stack (although complete penetration and some field overlap is preferably achieved to secure bonding rapidly).

It is noted that the present system, includes the use of a high-temperature resin or epoxy within a holder element to secure the core and winding elements in a preferred embodiment but the use of resin or epoxy is not required for operation and serves only to improve reliability and ease of use.

During operation, the present system with use of a ceramic cover plate 901B′ (or a high temperature metal or a high temperature polymeric plate cover) enable the use of substantially high temperatures prior to functional break-down. While conventional bonding temperature ranges are from approximately 250-375° F. or 380° F. depending upon the bonding systems used, the present system enables the use of temperatures as high as 900-1000° C. before final functional break down. As a consequence, the present system speeds inductive thermal bonding across the range of likely bonding temperatures desired by customers.

As noted above, the use of a continuous cooper pad further aids rapid thermal transfer to bond in a practice contradicted by the teachings of the related art. As a consequence, the copper pad center experiences the temperature as closely as possible to a true induced temperature proximate the cover plate 901B′ as measured by thermocouple 901F allowing for reliable thermal bonding control.

As a consequence, the present construction enables heat up rates to inductive bonding from approximately 10 seconds to 1 minute, depending upon a user desire. This is in complete contrast to the related art thermal cycle systems that operate on the order of multiple minutes to induce sufficient thermal bonding penetration for heating related lay-ups or stacks.

Referring now to FIGS. 25 and 26 it will be appreciated that respective top and bottom bond head assemblies 901A, 901B are positioned fixed to respective air cylinder end members 931 which are, in turn, joined to ends of operative air cylinders 932, 933 for each respective air cylinder unit 915, 915 for each bonding group. During operation and initial positioning, air cylinders 932, 933 are fully retracted (FIG. 25) and cooling system 924 containing cooling manifold 923 is not employed. Although it is recognized that cooling system 924 may be employed at any time or continuously throughout the bonding cycle. Following the initial bonding step, as respective bond heads 901 separate from the now-bonded lay-up, it is presently preferred that cooling systems 924 operate directly, allowing cooling to the as-bonded lay-up and to each bond head 901. It will also be appreciated, that while FIGS. 25 and 26 depict the use of dual-bonding head movement (dual use of air cylinder units 915, this is not required and only one bond head may be optionally movable (the other unit remaining fixed).

As a result of the present construction, it will be recognized that cooling system 928 may be employed at multiple times during the bonding cycle depending upon a consumers need. Additionally, cooling system 928 may be provided with multiple and differently-positioned cooling heads or cooling nozzles extending to cool multiple locations or to focus cooling in a preferred location during rapid cycling. Therefore, it is proposed that those of skill in the art, having appreciated the present disclosure, will recognize that the proposed bond head assembly and cooling system is readily adapted to diverse consumer needs while continuously providing improved reliability and cycle time.

Referring now to FIG. 27, it shall be recognized that the presently proposed bond head systems and assemblies may be employed in complex unified bonding systems 930, containing individual loading stations 930A and aligning stations 931B, and multiple bonding stations 900A, 900B, as shown. During use, system 903 may readily load, align, and begin bonding at a first station 900A, and then during bonding at station 900A, load, align and begin bonding at the second station 900B. A third or additional stations may be provided without departing from the scope and spirit of the present invention. Consequently, it will be appreciated by those of skill in the art, having reviewed the entire disclosure herein, that the present invention enables the use of multiple-bonding station systems for speedy processing.

Referring now to FIG. 28, it has been recognized by the applicant that due to the present construction (providing improved thermal capability), the risk of over or too-rapid heating may occur under non-programmed or un-controlled circumstances. This risk is balanced by the desire to have a very rapid heat up to speed cycle time and the need to avoid damage to the equipment and the bonded stack of sheets 917.

Consequently, it has been recognized that while core 901D may comprise any number of windings to function, a preferred range of function is achievable by selecting a preferable number of windings or turns. As noted below in Table 1, a listing of number of turns in coil 901D is presented with the respective measured induced inductances, and the standard deviation range relative to conventional measurements. In Table 1, a bond head assembly such as bond head assembly 901B as detailed in FIG. 20 is provided absent epoxy or resin so as to allow simple interchange of cores 901D with different numbers of windings. It will be recognized that the number of windings recognized herein may be adaptable based upon the gauge of wire employed in the coil and the quality of the metal therein.

TABLE 1

| Turns | Inductance |
|---|---|
| 56 turns | 347-360 uH (355 +/− 8 Uh) |
| 40 turns | 195-205 uH (200 +/− 5 uH) |
| 32 turns | 139-146 uH (142 +/− 3.6 Uh) |

An additional experiment, or series of experiments, was conducted using sets of similarly arranged bond heads 901, in opposing positions similar to those noted in FIG. 21, with a separation or gap of approximately 0.30 inches (+/−0.20 inches) so as to simulate measurable inductances and heating rates when only one or both bonding heads with differing windings and stack heights were employed. A thermocouple similar to 901F was employed between the spaced bonding heads as well as within each bonding head 901, and an inductance measuring device was employed to track the inductance generated (noting similarity to the results in Table 1). The results of the experiments are summarized in Table 2.

TABLE 2

| Turns for top/ | 0 | 10 | 20 | 30 | 40 | 50 | 60 |
|---|---|---|---|---|---|---|---|
| bottom head | Sec. | Sec. | Sec. | Sec. | Sec. | Sec. | Sec. |
| 56/56 | 31 | 121 | 163 | 198 | 225 | 250 | 268 |
| 40/40 | 30 | 183 | 268 | 314 | stopped | | |
| 32/32 | 32 | 227 | 326 | stopped | | | |
| 0/56 | 31 | 110 | 151 | 182 | 206 | 222 | 238 |

As is noted, due to the very rapid temperature gradient for the 40/40 and 32/32 turn cores the experiment was stopped to preserve the testing equipment. The graphical plot of Table 2 is noted in FIG. 28.

A number of items will be appreciated from FIG. 28. The first item of impact, is that the heating rate of the sole bond head (the 0 turns/56 turns circumstance for respective top and bottom heads) provides a heating rate the same as or nearly the same as that of the 56/56 turn case. Consequently, it is appreciated that the use of independent bond head assemblies (a single bond head) is a viable option and may be substantially effective for use in bonding practice without adaptation, and can be used independently of an opposing bonding head (top or bottom). This construction also substantially expands the freedom for bonding use within a sheet field or in alternative bonding systems according to a customer's needs. This ability to bond freely within the sheet field will allow the expansion of bonding applications and bonding-design freedom applications within the industry.

The second item recognized, is that for the present construction a pairing of the 32 turns/32 turns core bonding heat system provides optimal heating ramp rates so as to stay within the general operational temperature range (noted above) for the bonding resins employed by the industry (from approximately 10 seconds to one minute—much faster than the related art bonding times of multiple minutes). Thus, the present construction enables the use of rapid but controllable bonding and reduced bonding cycle times.

As a particular advantage, employing the unique features of thettual tailoring wherein the thin-film thermocouple construction 901F is employed directly above the central E- of the ferrite core, and similar parallel tracking thin thermal couples may be placed between respective cooper pads 914 and/or between respective cover layers 1 and monitored during thermal bonding; the tracking of the ramp and bonding rate, and thermal penetration of stacked layers 917 is readily achieved. Thus, the use of the present system allows users to employ either a single bond head or multiple bond heads, in multiple or movable positions, to achieve a controllable a thermal spectrum throughout a multiplayer thickness and ultimately improve bonding cycle efficiency.

As another alternative embodiment of the present invention, the bonding head systems noted herein may be optionally attached with cognizable minimal modification to the controllable motion systems as noted in Applicant's co-pending related applications U.S. Ser. No. 60/783,888 filed Mar. 20, 2006, now PCT/US07/64435 filed Mar. 20, 2007 (pending), the entire contents of which are herein incorporated by reference. Thus it is appreciated that the present system is readily managed to determine an optimum ramp rate (voltage/temperature) that is readily record-able in operational software and hence reliably repeatable in production environments.

As shown in FIGS. 29A-29B, a stack or layer S of printed circuit board PC (PC1-PC4 may be provided with information provided on a surface thereof in the form of a layered barcode B1 and/or a panel barcode B2, for example. The barcode may include information to ensure that the correct layer is being processed, to track the movement of the layer, the job through the factory, and/or to set up process parameters.

The printed circuit board may include a single sided board, a double sided board, inner layers of multilayer board, sub-laminations within a multilayer board, rigid boards, flex boars and rigid flex boards where both rigid and flex materials. In a multilayer board, the laminated board, inner layers are pressed to make a single board that is often referred to as a panel. Each of the individual inner layers must be identified separately from each individual layer. This identification may be accomplished by leaving a non-conductive area on each inner layer and etching or printing a separate information area on the top layer. This can be the top inner layer or the top outer layer. This information can also be placed on the bottom layer. Because of the range of materials (e.g., type, color, texture, etc.), as well as a range as to how the information is placed on the material, the lighting needs for reading or viewing the information may differ on a case-by-case basis. For example, laminate elements may include rigid, flexible, metallic, etc. materials. Due to the range of materials and surface properties, a variety of lighting solutions may be desirable. For example, diffusers (e.g., filters) may assist in reading metallic surfaces, and ultraviolet light may cause a barcode to fluoresce to assist in its reading. Light intensity may be adjusted by pulsing light or by modulating the voltage to the LED(s).

As shown in FIGS. 30A-30C, an integrated bonding station assembly 1100 may be substantially similar to the integrated bonding station assembly 900 described above except with the following differences described herein. In particular, the integrated bonding station assembly 1100 may alternatively or additionally include an activator switch 1102 for lighting which may be configured to move up/down along bidirectional arrow P, a barcode reader 1104, a direct lighting assembly 1106, a low angle lighting assembly 1108, and a back lighting assembly 1110.

The integrating bonding station assembly 1100 provides a means to supplement lighting to improve image quality of an image of a bar code which may be on the printed circuit board and viewed by an imaging/vision system. In particular, direct lighting from a similar location as the camera of barcode reader 1104 may be provided. In addition, low angle lighting from near the surface of the material within the information on it may be provided. Further, backlighting may be provided that may light through the printed circuit board and illuminate the information on the material surface. The barcode reader 1104 may include a lens and a light sensor that translates optical impulses into electrical ones to decode the data on the barcode provided on a surface of the laminate element. The lighting assemblies 1106, 1108, and 1110 may illuminate the barcode and may provide light of a specific waveform as necessary to interact with the materials of the barcode and/or laminate element as certain areas of the barcode will absorb light and others will reflect light and these patterns are translated by the barcode reader 1104 to correspond with particular information.

The varying lighting needs may be met by providing the following types of lighting: (a) direct lighting, (b) low angle lighting, and/or (c) backlighting. Moreover, the color of the light may be selected to be a specific color based on the core material qualities of the printed circuit board surface. The light may be colored or it may be a white light or may be in a non-visible wavelength. The bandwidth of the color may be controlled by the selection of particular lights, e.g., LEDs and/or filters that are placed over the light to change the color of the light. The intensity and/or wavelength of the light emitted may be modulated or predetermined by the selection of a plurality of LEDs of different wavelengths and/or intensities.

Further, a diffuser may be placed between the light and the material being viewed (e.g., the barcode on the printed circuit board) to improve the image quality. The diffuser may be used with each of the types of lighting described above, namely, (a) direct lighting, (b) low angle lighting, and/or (c) backlighting. In the case of direct lighting and low angle lighting, diffused lighting minimizes reflections from the metallic surfaces. With backlighting, a diffuser helps to soften the light as well as make the light more comfortable for an operator that is working in the area.

In addition, the light intensity can be adjusted with various means including adjusting the voltage to the lights, varying the pulsed on time, as in pulse width modulation, and by placing a diffuser or opaque material between the light and the information to be read. The light can also be strobed for greater light intensity and/or for conserving power when the reader or vision system is not active. In the case of a multilayer printed circuit board, each individual layer can include, for example, layer specification, job information, revision level, run number and/or process parameters. Each layer can be read to ensure that the correct layer is being processed, to track the movement of the layer, the job through the factory, and/or set up process parameters. In a multilayer printed circuit board, the laminated board (inner layers pressed to make a single board) often called a panel must have each individual layer identified separately. This may be accomplished, for example, by leaving a non-conductive material area (e.g., an area without copper) on each inner layer and by etching or printing information on a separate area on the top layer.

In the claims, means-plus-function or step-plus-function clauses are intended to cover the structures described or suggested herein as performing the recited function and not only structural equivalents but also equivalent structures. Thus, for example, although a nail, a screw, and a bolt may not be structural equivalents in that a nail relies on friction between a wooden part and a cylindrical surface, a screw's helical surface positively engages the wooden part, and a bolt's head and nut compress opposite sides of a wooden part, in the environment of fastening wooden parts, a nail, a screw, and a bolt may be readily understood by those skilled in the art as equivalent structures.

Having described at least one of the preferred embodiments of the present invention with reference to the accompanying drawings, it is to be understood that the invention is not limited to those precise embodiments, and that various changes, modifications, and adaptations may be effected therein by one skilled in the art without departing from the scope or spirit of the invention as defined in the appended claims.

What is claimed is:

1. An integrated bonding station for bonding laminate elements in a selected stack orientation, at least one of the laminate elements including a barcode on a surface thereof, the integrated boding station including a barcode reader assembly, comprising:
a barcode reader; and
a lighting assembly configured to illuminate a barcode disposed on a surface of at least one of the laminate element, the lighting assembly comprising:
a direct lighting assembly being configured to direct light onto the surface of the at least one laminate element;
a low angle lighting assembly being configured to direct light near the surface; and
a back lighting assembly being configured to direct light onto an opposing side of the surface.

2. The integrated bonding station of claim 1, wherein each of the direct lighting assembly, low angle lighting assembly, and back lighting assembly are configured to provide light of a selected wavelength and of a selected intensity.

3. The integrated bonding station of claim 1, further comprising:
a diffuser that is configured to be placed between at least one of the lighting assemblies and the barcode to be read.

4. The integrated bonding station of claim 1, wherein the surface of the laminate element is metallic.

5. The integrated bonding station of claim 1, wherein the laminate element includes both rigid and flexible materials.

6. The integrated bonding station of claim 1, wherein the barcode is disposed on at least one or an upper surface and a lower surface of the laminate element.

7. The integrated bonding station of claim 3, wherein a light emitted by the lighting assembly is pulsed.

8. The integrated bonding station of claim 7, wherein at time the light is pulsed is varied.

9. The integrated bonding station of claim 7, wherein a pulse width of the light emitted by the lighting assembly is modulated.

10. The integrated bonding station of claim 1, wherein at least one of an intensity and wavelength of light emitted by the light assembly corresponds to an arrangement of LEDs selected.

11. The integrated bonding station of claim 1, wherein at least one of an intensity and wavelength of light emitted by the light assembly corresponds to adjusting a voltage.

12. The integrated bonding station of claim 1, wherein the light includes ultraviolet light.
